(19) United States
(12) Patent Application Publication
(10) Pub. No.: US 2026/0283256 A1
(43) Pub. Date: Sep. 24, 2026

(54) A Method of Monitoring an Aerosol Generating System and an Aerosol Generating System

(71) Applicant: JT International SA, Geneva (CH)

(72) Inventors: Grzegorz Aleksander Pilatowicz, Grens (CH); Hajime Fujita, Geneva (CH)

(73) Assignee: JT International SA, Geneva (CH)

(21) Appl. No.: 19/472,942

(22) PCT Filed: Apr. 9, 2024
(86) PCT No.: PCT/EP2024/059613

§ 371 Date: Oct. 6, 2025

(30) Foreign Application Priority Data
Apr. 21, 2023 (EP) 23169173.4

(51) Int. Cl. A24F 40/53; A24F 40/51; A24F 40/90; G01R 31/389; G01R 31/392

(52) U.S. Cl. CPC A24F 40/53; A24F 40/51; A24F 40/90; G01R 31/389; G01R 31/392

(57) ABSTRACT

A method of monitoring an aerosol generating system is described. The aerosol generating system includes a first energy storage device configured to supply power to generate an aerosol. The method includes charging the first energy storage device with a direct current (DC) charging current. While the first energy storage device is being charged, an alternating current (AC) signal is applied to the first energy storage device. Voltage and current measurements obtained in response to the applied AC signal are used to estimate or determine the impedance of the first energy storage device. The impedance of the first energy storage device is used to estimate or determine a condition of the first energy storage device, e.g., to determine a fault or other condition of the energy storage device in response to changes in the internal impedance.

### TECHNICAL FIELD

The present disclosure relates generally to a method of monitoring an aerosol generating system, and in particular to an aerosol generating system which may include an aerosol generating article which is configured to be received in an aerosol generating device for generating an aerosol for inhalation by a user. The aerosol generating article may comprise an aerosol generating material or substrate.

The present disclosure is particularly applicable to a portable (hand-held) aerosol generating device.

### TECHNICAL BACKGROUND

Devices which heat, rather than burn, an aerosol generating material to produce an aerosol for inhalation have become popular with consumers in recent years. A commonly available reduced-risk or modified-risk device is the heated material aerosol generating device, or so-called heat-not-burn device. Devices of this type generate an aerosol or vapour by heating an aerosol generating material to a temperature typically in the range 150° C. to 300° C. This temperature range is quite low compared to an ordinary cigarette. Heating the aerosol generating material to a temperature within this range, without burning or combusting the aerosol generating material, generates a vapour which typically cools and condenses to form an aerosol for inhalation by a user of the device.

Such devices may use one of a number of different approaches to provide heat to the aerosol generating material. All approaches for heating the aerosol generating material normally require some sort of rechargeable power source or energy storage device such as a battery (e.g., a lithium-ion secondary battery or battery pack). The energy storage device is typically not replaceable or accessible to the user. This means that the manufacturer of the aerosol generating device has complete control over the type and quality of the energy storage device, thereby often avoiding the need to carry out complex monitoring of the condition of the energy storage device. It also avoids the need to design the aerosol generating device in a way that allows it to support a wide range of different energy storage device types. However, there is also a desire to make aerosol generating devices more sustainable and to have a more serviceable design that allows the energy storage device to be replaced by the user if necessary. If the energy storage device is replaceable, it may be necessary to check if a correct type of energy storage device has been inserted or connected, and there will normally be a need to monitor a condition of the energy storage device to ensure safe operation. Monitoring the condition of an energy storage device may be particularly important when it is being charged. This is often the most safety critical state, especially for lithium-ion secondary batteries. Larger energy storage devices may include a temperature sensor such as a thermocouple or thermistor for monitoring a temperature of the energy storage device.

The temperature sensor may typically be located on an outer surface of the energy storage device housing and is therefore only capable of monitoring its surface temperature. It is expected that a fault will result in an increase in the temperature of the energy storage device, and that this will be detected by the temperature sensor.

Temperature increases may be the result of internal faults such as interface breakdown or uncontrollable reactions in the electrodes, for example, and may result in catastrophic failures such as thermal runaway. Depending on where the fault and the temperature sensor are located, there may be a significant delay in detection. For example, if the temperature sensor is located at one end of the energy storage device and the fault occurs at the opposite end, it may take time for any localised temperature increase caused by the fault to be detected by the temperature sensor. There is also a risk that the temperature sensor may not always be in good thermal contact with the outer surface of the housing, e.g., because of the aging of the tape or adhesive that is used to fix it in position. Embodiments of the present disclosure therefore seek to provide an aerosol generating system that may perform improved monitoring of an energy storage device, particularly when it is being charged. The internal impedance of the energy storage device may be monitored continuously during charging because it is known that the internal impedance relates generally to the internal temperature of the energy storage device. More particularly, it is known that internal impedance is normally inversely proportional to the internal temperature. More particularly, this inverse relationship between internal impedance and temperature generally applies in the expected operating temperature range of the energy storage device for which ionic conductivity of the electrolyte is the main component of internal impedance. The higher the temperature, the better the ionic conductivity. (At higher temperatures, there may be increased resistance from other components of the energy storage device such as current collectors, tabs, terminals etc.) that compensates for the better ionic conductivity of the electrolyte.) An internal fault in the energy storage device that leads to an increase in temperature will therefore also lead to a corresponding decrease in the internal impedance. The proposed monitoring may result in a more accurate determination of the condition of the energy storage device and ensure that the aerosol generating device may be used safely even in situations where the energy storage device is replaceable.

### SUMMARY OF THE DISCLOSURE

According to a first aspect of the present disclosure, there is provided a method of monitoring an aerosol generating system comprising a first energy storage device configured to supply power to generate an aerosol, the method comprising:
charging the first energy storage device with a direct current (DC) charging current supplied by an external power source or a second energy storage device of the aerosol generating system;
while the first energy storage device is being charged, applying an alternating current (AC) signal to the first energy storage device;
using voltage and current measurements obtained in response to the applied AC signal to estimate or determine the internal impedance of the first energy storage device; and
using the internal impedance of the first energy storage device to estimate or determine a condition of the first energy storage device, e.g., to estimate or determine a fault condition or a condition which may be indicative of, or related to, device performance in response to changes in the internal impedance during charging.

The aerosol generating system may comprise an aerosol generating device. The aerosol generating device is typically a hand-held, portable, device.

The first energy storage device may be electrically connectable to an external power source, e.g., a universal serial bus (USB) charger. The first energy storage device may be electrically connected to a charging circuit, which may be electrically connectable to the external power source. The charging circuit may be used to charge the first energy storage device from the external power source.

The first energy storage device may also be charged by a second energy storage device of the aerosol generating system. The first and second energy storage devices may be part of the aerosol generating device, for example. The second energy storage device may also be charged by the external power source, optionally by means of a reversible buck/boost regulator that is electrically connected to the second energy storage device and the charging circuit mentioned above.

The first energy storage device may have any suitable construction for use in an aerosol generating device and is configured to supply power to generate an aerosol. The first energy storage device may be a lithium-ion secondary battery or a capacitor or capacitor module, for example. The optional second energy storage device may also have any suitable construction for use in an aerosol generating device and is configured to supply power to generate an aerosol. The second energy storage device may be a lithium-ion secondary battery or a capacitor or capacitor module, for example.

The first and second energy storage devices of the aerosol generating system may be the same or different. For example, one of the energy storage devices may be a lithium-ion secondary battery and the other energy storage device may be a capacitor or capacitor module. Each capacitor may have any suitable construction, but in a preferred embodiment may be an electric double-layer supercapacitor. A capacitor may have a higher power density than a conventional power source such as a battery. As mentioned above, the first and second energy storage devices may be charged by an external power source such as a USB charger, for example.

Each energy storage device may comprise an electrolyte, a pair of electrodes and a porous separator between the electrodes. The pair of electrodes typically comprises a positive electrode (or cathode) and a negative electrode (or anode). The AC signal may be applied across the positive electrode and the negative electrode. The electrodes and the separator are immersed in the electrolyte. Each energy storage device may comprise a positive terminal electrically connected to the positive electrode and a negative terminal electrically connected to the negative electrode. The positive and negative terminals allow each energy storage device to be connected to an external circuit. At least one of the first and second energy storage devices may be detachable or removable where its positive and negative terminals may be in electrical contact with corresponding fixed terminals of an external circuit of the aerosol generating device when it is physically connected to the device, for example. An aerosol generating device that includes a removable energy storage device may be more sustainable and allows a faulty or degraded energy storage device to be removed and replaced by the user.

In the case of a capacitor, electrical charge is stored in the electrical field between the electrodes and the capacitance is a function of the surface area of the electrodes, the distance between them, and the dielectric constant of the separator material. When the capacitor is charged by an external circuit connected to the pair of electrodes, cations in the electrolyte migrate toward the negative electrode and the anions migrate to the positive electrode, while the electrons travel through the external circuit from the negative to the positive electrode. Two layers of charge with opposite polarity (an electric double-layer) are therefore formed at the interfaces with the electrodes. When charging finishes, positive electric charges on the positive electrode and anions in the electrolyte attract each other while negative electric charges on the negative electrode and cations in the electrolyte attract each other in order to stabilize the double layers on the electrodes. A stable voltage is generated. When the capacitor is discharged, the reverse processes happen.

In the case of a lithium-ion secondary battery, for example, during charging, the electrolyte carries positively charged lithium ions from the positive electrode to the negative electrode through the separator and electrons travel through the external circuit from the negative electrode to the positive electrode. When the lithium-ion secondary battery is discharged, lithium ions embedded in the negative electrode are released and move back to the positive electrode and electrons travel through the external circuit from the positive electrode to the negative electrode.

Each electrode may comprise at least one carbon-based electrode layer, for example, a layer of porous charcoal material or activated carbon which has a high specific surface area per volume and compatibility with the proposed electrolyte. In the case of a lithium-ion secondary battery, the positive electrode may include lithium metal oxide (e.g., lithium cobalt oxide (LiCoO₂)) or other suitable material and the negative electrode may include graphite, for example.

Each electrode may further comprise a current collector, which may comprise a metal foil layer, for example, an aluminium foil layer. Each current collector may encourage electron travelling via the external circuit. A carbon-based electrode layer may be positioned adjacent one or both sides of a current collector. Each carbon-based electrode layer may be formed as a coating. Such electrodes may be manufactured relatively easily and cheaply using materials that are already known to be used in aerosol generating articles. Each current collector may encourage electron travelling via the external circuit.

The separator must provide dielectric separation between the pair of oppositely charged electrodes. The separator also stores electrolyte in its pores and permits the passage of cations and anions during the charging and discharging processes. The separator may comprise any suitable material.

The AC signal applied to the first energy storage device may be superimposed on the DC charging current from the external power source or the second energy storage device.

If the aerosol generating system further comprises a second energy storage device, the method may further comprise charging the first and second energy storage devices with a DC charging current supplied by an external power source (e.g., a USB charger).

While the first and second energy storage devices are being charged, the method may further comprise superimposing the AC signal on the DC charging current supplied to the first energy storage device.

Voltage measurements may be provided by a voltage sensing circuit that may comprise a voltage divider circuit, for example. Current measurements may be provided by a current sensing circuit that may comprise a current sensing amplifier or other suitable current sensor. These voltage and current sensing circuits allow the condition of the first energy storage device (and in some embodiments, the optional second energy storage device) to be estimated or determined reliably and at low cost. More particularly, it may also be possible for an AC signal to be applied to the second energy storage device while it is being charged. The AC signal is preferably applied to each energy storage device sequentially. In other words, an AC signal may be applied to the first energy storage device so that a condition of the first energy storage device may be estimated or determined, and an AC signal may then be applied to the second energy storage devices so that a condition of the second energy storage device may be estimated or determined. The AC signal that is applied to each energy storage device may be the same or different.

The voltage and current measurements may be provided to a controller, which estimates or determines the internal impedance of the first energy storage device. In a continuous process for monitoring a condition of the first energy storage device, a series of internal impedance values are preferably estimated or determined while it is being charged. For fast and repeatable determination, the frequency of the AC signal may preferably be in the range of about 100 Hz to about 3 kHz, and more preferably in the range of about 800 Hz to about 1.2 kHz, for example.

The root mean squared (RMS) values of the voltage and current Vᵣₘₛ and Iᵣₘₛ may be determined as follows:

$${V}_{rms}^{2} = \frac{1}{T} {\int }_{0}^{T} {v}^{2} ( t ) dt$$

$${I}_{rms}^{2} = \frac{1}{T} {\int }_{0}^{T} {i}^{2} ( t ) dt$$

where T is the period over which the averaging of the instantaneous voltages and currents is performed.

Once the RMS values are known for the given frequency f of the AC signal (f=)ω/2π where ω is the angular frequency), the magnitude of the internal impedance Z may be estimated or determined as follows:

$$\vert Z ( ω ) \vert = \sqrt{\frac{{V}_{rms}^{2} ( ω )}{{I}_{rms}^{2} ( ω )}}$$

The internal impedance values are used to estimate or determine a condition of the first energy storage device.

For example, one or more internal impedance values may be determined when charging starts and used as an initial value. The initial value may be an average of two or more internal impedance values.

The initial value may be compared against one or more thresholds to estimate or determine an initial condition of the first energy storage device. For example, it is known that internal impedance increases with the number of charging cycles (i.e., as the energy storage device ages) and if the initial value is above a first threshold it may indicate that the first energy storage device needs to be replaced and if it is above a second threshold, that is higher than the first threshold, it may indicate that the first energy storage device is not suitable for operation and that charging should be stopped. An appropriate notification may be provided to the user.

Subsequent internal impedance values may be determined during the charging of the first energy storage device. It is known that internal impedance is normally inversely proportional to the temperature of an energy storage device in the expected operating temperature range of the energy storage device. Any increase in the temperature of the energy storage device will therefore normally result in a respective decrease in its internal impedance, and vice versa. Such changes in temperature and internal impedance will be relatively small if the energy storage device is not faulty or degraded and is charging normally. But in the case of a fault, for example, the changes may be more significant—i.e., there will be a more significant change in the subsequent internal impedance values determined by the monitoring process. As described in more detail below, the internal impedance values may be used to in addition to, or instead of, temperature measurements provided by a temperature sensor (e.g., a thermocouple or thermistor) that may be integrated with the first energy storage device. The temperature sensor may provide measurements of a surface temperature of the first energy storage device, for example. The internal impedance values may be used to check the validity of the temperature measurements provided by the temperature sensor.

The subsequent internal impedance values may be compared against one or more thresholds to estimate or determine a condition of the first energy storage device during charging. For example, if a subsequent value is below a threshold it may indicate that the temperature of the energy storage device is too high and that charging should be stopped. It will be understood that a significant decrease in the internal impedance is likely to be indicative of a fault which requires the charging to be stopped as soon as possible. Such monitoring may allow a more rapid and reliable response as compared with relying on measurements of a temperature of the first energy storage device, for example. In particular, it has been shown that if an energy storage device develops a fault during charging, the internal impedance may start to decrease, and therefore may fall below a predefined threshold, before there is any significant increase in the measured temperature of the energy storage device. If a fault condition is detected, charging may be stopped and the user may be notified. It may be necessary to remove and replace the faulty energy storage device so that the aerosol generating device may be operated again safely.

The threshold may optionally be determined with reference to the initial value of the internal impedance. For example, the threshold may be set so that the internal resistance is below the threshold when it has decreased by about 20-40% of the initial value. This may allow for changes in the internal impedance as the number of charging cycles increases—i.e., as the first energy storage device ages.

For some types of energy storage device, the internal impedance may decrease and then subsequently increase if there is a fault. If a subsequent value of internal impedance is above a threshold it may indicate that the temperature of the energy storage device is too high and that charging should be stopped.

The same continuous process may also be used to monitor a condition of the second energy storage device if an AC signal is applied while it is being charged.

According to a second aspect of the present disclosure, there is provided a method of monitoring an aerosol generating system comprising an energy storage device (e.g., a Lithium-ion secondary battery or a capacitor or capacitor module as described above) configured to supply power to generate an aerosol, and a temperature sensor configured to measure a temperature of the energy storage device, the method comprising:
charging the energy storage device with a DC charging current;
while the energy storage device is being charged, applying an AC signal to the energy storage device;
using voltage and current measurements obtained in response to the applied AC signal to estimate or determine the internal impedance of the energy storage device; and
using the internal impedance of the energy storage device to determine if the temperature measurements provided by the temperature sensor are valid.

The temperature sensor may be a thermocouple or thermistor, for example, and may be positioned on an outer surface of a housing of the energy storage device. The temperature sensor is configured to measure a temperature of the energy storage device, e.g., a surface temperature. Internal impedance values may be estimated or determined as described above and may be considered to be a better indication of the internal temperature of the energy storage device—i.e., a temperature inside the device housing that may differ from the surface temperature. Temperature measurements provided by the temperature sensor during charging may be compared with the internal impedance values that are estimated or determined during charging. The comparison may be used to determine if the temperature measurements provided by the temperature sensor are valid or not. For example, if the subsequent internal impedance values decrease without a respective increase in the temperature measurements also being detected by the temperature sensor, the validity of the temperature measurements may be set as “not valid” and the user may be notified.

According to a third aspect of the present disclosure, there is provided an aerosol generating system comprising:
a first energy storage device (e.g., a Lithium-ion secondary battery or a capacitor or a capacitor module);
an inverter electrically connected to the first energy storage device and configured to supply an AC signal;
a superimposing circuit electrically connected to the inverter and the first energy storage device, wherein the superimposing circuit is configured to impose the AC signal supplied by the inverter on a DC charging current supplied by an external power source (e.g., a USB charger) or a second energy storage device (e.g., a Lithium-ion secondary battery or a capacitor or a capacitor module) of the aerosol generating system; and
a controller configured to:
   supply a DC charging current and a superimposed AC signal to the first energy storage device to charge the first energy storage device,
   use voltage and current measurements obtained in response to the AC signal to estimate or determine the internal impedance of the first energy storage device, and
   use the internal impedance to estimate or determine a condition of the first energy storage device.

The aerosol generating system may further comprise a charging circuit electrically connectable to an external power source. A switch such as a semiconductor switch may be electrically connected between the charging circuit and the first energy storage device. An input of the superimposing circuit may be electrically connected between the charging circuit and the switch and an output of the superimposing circuit may be electrically connected between the switch and the first energy storage device. The controller may be further configured to open the switch when the AC signal is supplied to the first energy storage device. The controller may be further configured to close the switch when the AC signal is not supplied to the first energy storage device and a DC charging current supplied by the external power source is supplied to the first energy storage device.

The aerosol generating system may further comprise a second energy storage device (e.g., a lithium-ion secondary battery or a capacitor or capacitor module). An input of the superimposing circuit may be electrically connected to the second energy storage device. Alternatively, an output of the superimposing circuit may be electrically connected to the second energy storage device.

The aerosol generating system may further comprise a first switching circuit electrically connected between the superimposing circuit and the second energy storage device.

The first switching circuit may be electrically connectable to an external power source.

The first switching circuit may be configured to selectively connect an input of the superimposing circuit (e.g., a non-inverting input terminal of an operational amplifier of the superimposing circuit) to one of the second energy storage device and the external power source. The first switching circuit may also be electrically connected to the first energy storage device. The first switching circuit may be configured to selectively connect the input of the superimposing circuit to one of the first energy storage device, the second energy storage device, and the external power source. The first switching circuit may be a single-pole triple-throw switching circuit, for example.

The aerosol generating system may further comprise a second switching circuit electrically connected between the inverter and the second energy storage device. The second switching circuit may be electrically connectable to the external power source.

The second switching circuit may be configured to selectively connect an input of the inverter (e.g., an input voltage terminal of the inverter) to one of the second energy storage device and the external power source. The second switching circuit may also be electrically connected to the first energy storage device. The second switching circuit may be configured to selectively connect the input of the inverter to one of the first energy storage device, the second energy storage device, and the external power source.

The second switching circuit may be a single-pole triple-throw switching circuit, for example.

The aerosol generating system may further comprise a voltage sensing circuit configured to measure the voltage across the first energy storage device when the AC signal is supplied to the first energy storage device. The voltage sensing circuit may be electrically connected between an output of the superimposing circuit (e.g., an output terminal of the operational amplifier of the superimposing circuit) and the first energy storage device.

The aerosol generating system may further comprise a current sensing circuit configured to measure the current through the first energy storage device when the AC signal is supplied to the first energy storage device. The current sensing circuit may include a shunt resistor and a current sensing amplifier electrically connected with the shunt resistor. The aerosol generating system may further comprise a third switching circuit electrically connected to the first energy storage device and configured to selectively connect the first energy storage device directly to ground or to ground via the shunt resistor of the current sensing device. More particularly the first energy storage device will be connected to ground via the shunt resistor when the first energy storage device is being charged and the AC signal is superimposed on the DC charging current supplied to the first energy storage device.

If the aerosol generating system includes a second energy storage device to which an AC signal may also be applied during charging, the aerosol generating system may further comprise a third switching circuit electrically connected between the superimposing circuit and the first and second energy storage devices. The third switching circuit may be configured to selectively connect the output of the superimposing circuit to one of the first and second energy storage devices. The third switching circuit may include an input terminal and two output terminals, each output terminal being selectively electrically connected to the positive terminal of a respective energy storage device. The third switching circuit may be controlled by the controller, e.g., in response to a select signal which selects between the output terminals. The single superimposing circuit may selectively output the superimposed AC signal to the respective energy storage device by means of the third switching circuit. This means that there is no need to provide a separate superimposing circuit for each energy storage device and the electrical circuit of the aerosol generating device is kept as simple as possible. The third switching circuit may comprise a single-pole double-throw switching circuit.

The aerosol generating system may further comprise a plurality of fourth switching circuits. Each fourth switching circuit may be electrically connected to a respective energy storage device and configured to selectively connect the negative terminal of the respective energy storage device directly to ground when the energy storage device is being discharged, or to ground via the shunt resistor of the current sensing device when the energy storage device is being charged and the AC signal is applied. Each fourth switching circuit may include an input terminal and two output terminals, one output terminal being electrically connected to the ground connection of the current sensing circuit and the other output terminal being electrically connected to one end of the shunt resistor. The other end of the shunt resistor is electrically connected to ground. The input terminal of each fourth switching circuit may be electrically connected to the negative terminal of the respective energy storage device. Each of the fourth switching circuits may comprise a single-pole double-throw switching circuit. A single current sensing circuit may be selectively connected to each of the first and second energy storage devices by means of the fourth switching circuits. This means that multiple current sensing circuits are not needed. It also minimises the number of terminals or pins of the controller that are utilised. Each fourth switching circuit may be controlled by the controller, e.g., in response to a select signal which selects between the output terminals. A common select signal may be provided to the third switching circuit and each fourth switching circuit to provide coordinated switching control.

The aerosol generating system may include an aerosol generating device configured to heat an aerosol generating material or substrate, without burning the aerosol generating material, to volatise at least one component of the aerosol generating material and thereby generate a heated vapour which cools and condenses to form an aerosol for inhalation by a user of the aerosol generating device during a vaping session. The aerosol generating device may generate an aerosol in other ways, e.g., by using an ultrasonic transducer to atomise a liquid aerosol forming substrate.

In general terms, a vapour is a substance in the gas phase at a temperature lower than its critical temperature, which means that the vapour may be condensed to a liquid by increasing its pressure without reducing the temperature, whereas an aerosol is a suspension of fine solid particles or liquid droplets, in air or another gas. It should, however, be noted that the terms ‘aerosol’ and ‘vapour’ may be used interchangeably in this specification, particularly with regard to the form of the inhalable medium that is generated for inhalation by a user.

The aerosol generating device may comprise a heating chamber for receiving at least part of an aerosol generating material, and a heater configured to heat the aerosol generating material to generate an aerosol. The heater may be a low power thin film heater, printed heater etc. An induction heater may be preferred. An induction heater may comprise an induction coil and a susceptor and may be configured to heat the aerosol generating material. For example, the induction coil may be positioned adjacent an aerosol generating space or heating chamber of the aerosol generating device that is designed to receive the aerosol generating material, where the aerosol generating material is optionally part of an aerosol generating article or consumable that is received in the aerosol generating device in use. When the induction heater is used to heat the aerosol generating material, an alternating electromagnetic field is generated by the induction coil. A susceptor may be associated with the aerosol generating material, e.g., positioned adjacent to or embedded in the aerosol generating material, and may be part of the aerosol generating article or the aerosol generating device. The susceptor couples with the electromagnetic field and generates heat due to eddy currents and/or magnetic hysteresis, which heat is then transferred from the susceptor to the aerosol generating material. To generate the alternating electromagnetic field necessary for induction heating, the device may further comprise an inverter that is electrically connected to the induction coil. The same inverter may also be used to generate the AC signal that is applied to the first energy storage device to estimate or determine its condition. In particular, the inverter may be selectively electrically connected to the first energy storage device and the induction coil of the induction heater, e.g., by a suitable switching circuit.

The aerosol generating material may comprise any type of solid or semi-solid material.

Example types of aerosol generating solids include powder, granules, pellets, shreds, strands, particles, gel, strips, loose leaves, cut filler, porous material, foam material or sheets. The aerosol generating material may comprise plant derived material and in particular, may comprise tobacco. It may advantageously comprise reconstituted tobacco, for example including tobacco and any one or more of cellulose fibres, tobacco stalk fibres and inorganic fillers such as calcium carbonate (CaCO₃).

Consequently, the aerosol generating device may be referred to as a “heated tobacco device”, a “heat-not-burn tobacco device”, a “device for vaporising tobacco products”, and the like, with this being interpreted as a device suitable for achieving these effects.

The features disclosed herein are equally applicable to devices which are designed to vaporise any aerosol generating material, including a liquid material or substrate.

As mentioned briefly above, the aerosol generating material may form part of an aerosol generating article that is received in the aerosol generating device, for example by inserting the aerosol generating article into an aerosol generating space or heating chamber of the aerosol generating device. The aerosol generating article may include a filter segment, for example comprising cellulose acetate fibres, at a proximal end of the aerosol generating article. The filter segment may constitute a mouthpiece filter and may be in coaxial alignment with the aerosol generating material. One or more vapour collection regions, cooling regions, and other structures may also be included in some designs. For example, the aerosol generating article may include at least one tubular segment upstream of the filter segment. The tubular segment may act as a vapour cooling region. The vapour cooling region may advantageously allow the heated vapour generated by heating the aerosol generating material to cool and condense to form an aerosol with suitable characteristics for inhalation by a user, for example through the filter segment.

The aerosol generating material may comprise an aerosol-former. Examples of aerosol-formers include polyhydric alcohols and mixtures thereof such as glycerine or propylene glycol. Typically, the aerosol generating material may comprise an aerosol-former content of between approximately 5% and approximately 50% on a dry weight basis. In some embodiments, the aerosol generating material may comprise an aerosol-former content of between approximately 10% and approximately 20% on a dry weight basis, and possibly approximately 15% on a dry weight basis.

Upon being heated, the aerosol generating material may release volatile compounds.

The volatile compounds may include nicotine or flavour compounds such as tobacco flavouring.

The aerosol generating material may be a liquid material or substrate and the device may comprise an atomising arrangement to atomise the liquid material or substrate, including without heating. The liquid material or substrate may also be heated.

### BRIEF DESCRIPTION OF THE DRAWINGS

FIG. 1 is a diagrammatic view of an example of an aerosol generating system comprising an aerosol generating device and an aerosol generating article;

FIG. 2 is a schematic representation of an example of an electrical circuit of the aerosol generating device; and

FIGS. 3 to 10 are schematic representations of the example of the electrical circuit of FIG. 2 showing different monitoring processes.

### DETAILED DESCRIPTION OF EMBODIMENTS

Embodiments of the present disclosure will now be described by way of example only and with reference to the accompanying drawings.

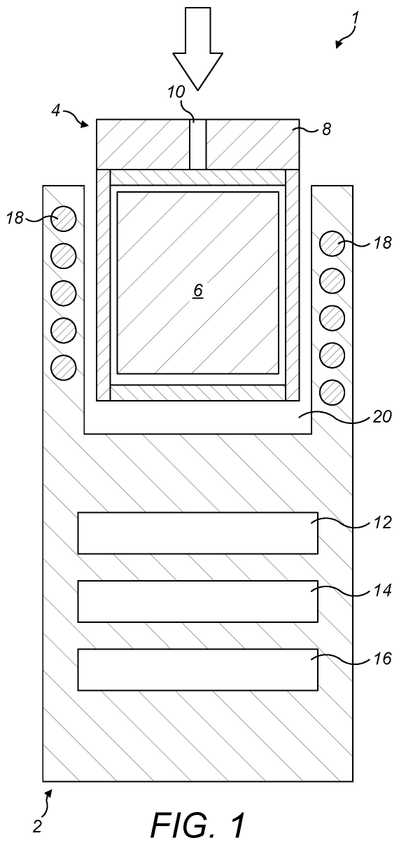

Referring initially to FIG. 1, there is shown diagrammatically an example of an aerosol generating system 1 including an aerosol generating device 2 and an aerosol generating article 4.

The aerosol generating article 4 may be generally cylindrical and include aerosol generating material 6. At the proximal end, the aerosol generating article 4 includes a mouthpiece 8 having an outlet 10 through which a user may inhale an aerosol that is generated by heating the aerosol generating material 6.

The aerosol generating device 2 includes an electrical circuit 12, a first energy storage device 14 such as a battery (e.g., a lithium-ion secondary battery), and a second energy storage device 16 such as a capacitor or capacitor module (e.g., one or more electric double-layer capacitors).

The aerosol generating device 2 may optionally include one or more heaters or other aerosol generators. The aerosol generating device 2 shown in FIG. 1 includes an induction heater with an induction coil 18 that is arranged adjacent an aerosol generating space or heating chamber 20 for heating the aerosol generating material 6 when the aerosol generating article 4 is inserted in the aerosol generating device 2. The aerosol generating article 4 may include one or more susceptors (not shown) that couple with the electromagnetic field and generate heat due to eddy currents and/or magnetic hysteresis, which heat is then transferred from the susceptor to the aerosol generating material 6. It will be readily understood that other aerosol generators may be used, including those that are configured to generate an aerosol without heating, e.g., by using an ultrasonic transducer to atomise a liquid aerosol forming substrate.

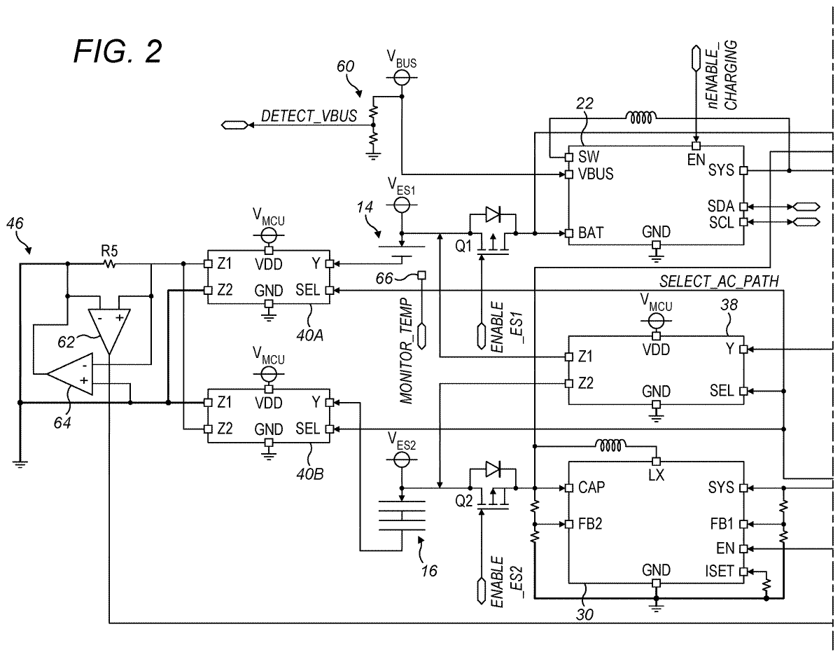

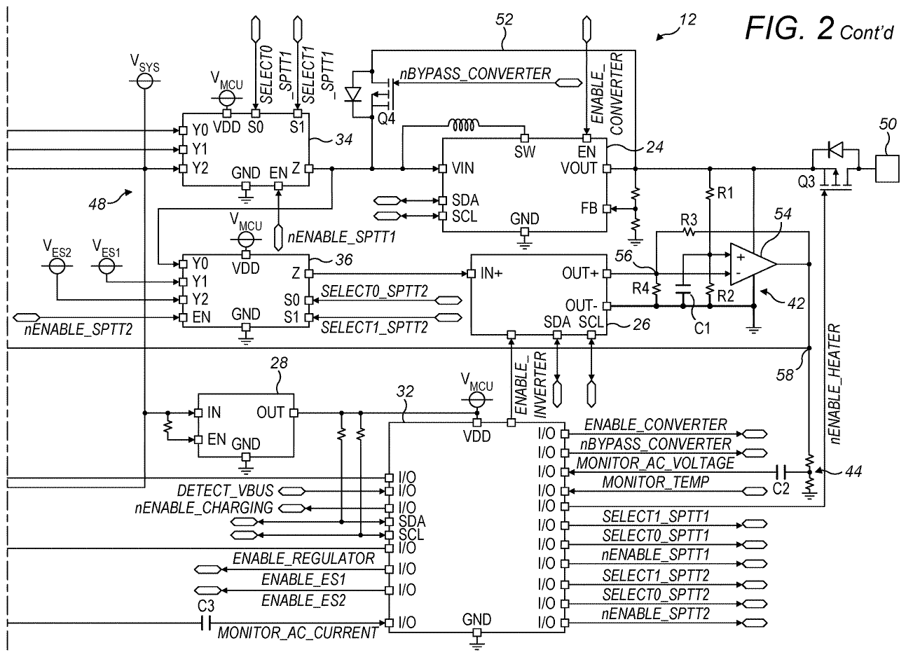

An example of an electrical circuit 12 is shown in FIG. 2. The electrical circuit 12 includes:
a charging circuit 22,
a DC/DC converter 24,
an inverter 26,
a low-dropout (LDO) regulator 28,
a reversible buck/boost regulator 30,
a microcontroller unit (MCU) 32,
a first switching circuit 34,
a second switching circuit 36,
a third switching circuit 38,
a pair of fourth switching circuits 40A, 40B,
a superimposing circuit 42,
a voltage sensing circuit 44,
a current sensing circuit 46, and
a temperature sensor 66 that is integrated with the first energy storage device 14.

The charging circuit 22, DC/DC converter 24, inverter 26, LDO regulator 28, reversible buck/boost regulator 30, MCU 32, first switching circuit 34, second switching circuit 36, third switching circuit 38, and fourth switching circuits 40A, 40B may be implemented as integrated circuits.

The charging circuit 22 includes:
an input terminal (labelled “VBUS”) electrically connectable to an external power source (not shown),
a battery terminal (labelled “BAT”) electrically connected to the positive terminal of the first energy storage device 14, i.e., the lithium-ion secondary battery, by means of a first semiconductor switch Q1,
a system terminal (labelled “SYS”) electrically connected to a system bus 48,
a switching node terminal (labelled “SW”) electrically connected to the system terminal by means of an inductor,
a ground terminal (labelled “GND”) electrically connected to ground,
a serial data terminal (labelled “SDA”) and a serial clock terminal (labelled “SCL”) that are electrically connected to corresponding terminals of the MCU 32, and
an enable terminal (labelled “EN”) electrically connected to a first input/output terminal (labelled “I/O”) of the MCU 32 and which allows the MCU 32 to enable charging of the first energy storage device 14 from the external power source (not shown).

The charging circuit 22 may be used to charge the first energy storage device 14 from the external power source (e.g., a universal serial bus (USB) charger, not shown) and to provide an output voltage at the system terminal to the system bus 44. The output voltage at the system terminal of the charging circuit 22 may be provided by the external power source (not shown) and/or the first energy storage device 14 that are respectively connected to the input terminal and the battery terminal of the charging circuit 22. The charging circuit 22 may allow the external power source (not shown) to charge the first energy storage device 14 and provide an output voltage at the system terminal at the same time. For example, it may be possible to use the external power source (not shown) to simultaneously charge the first energy storage device 14 and the second energy storage device 16—in the latter case through the system bus 48 and the reversible buck/boost regulator 30 described in more detail below. In FIG. 2, the voltage of the first energy storage device 14 is labelled “V_{ES1}” and the voltage of the second energy storage device 16 is labelled “V_{ES2}”. The voltage of the external power source is labelled “V_{BUS}”.

The first switching circuit 34 is a single-pole triple-throw (SPTT) switch and includes:
a first input terminal (labelled “Y0”) electrically connected between the first semiconductor switch Q1 and the battery terminal of the charging circuit 22,
a second input terminal (labelled “Y1”) electrically connected to the positive terminal of the second energy storage device 16 by means of a second semiconductor switch Q2 and to the capacitor terminal (labelled “CAP” of the reversible buck/boost regulator 30,
a third input terminal (labelled “Y2”) electrically connected to the system bus 48,
an output terminal (labelled “Z”),
a pair of select terminals (labelled “S0” and “S1”) respectively electrically connected to second and third input/output terminals (labelled “I/O”) of the MCU 32 and which allow the MCU 32 to selectively control which input terminal is connected to the output terminal by means of two select signals—i.e., to select if the output terminal Z is electrically connected to: (i) the junction between the battery terminal of the charging circuit 22 and the first semiconductor switch Q1 by means of the first input terminal Y0, (ii) the junction between the capacitor terminal of the reversible buck/boost regulator 30 and the second semiconductor switch Q2 by means of the second input terminal YT, or (iii) the system bus 48 by means of the third input terminal Y2,
a power supply terminal (labelled “VDD”) electrically connected to the voltage output terminal of the LDO regulator 28 and receives a regulated voltage supply—see below,
an enable terminal (labelled “EN”) electrically connected to a fourth input/output terminal (labelled “I/O”) of the MCU 32 and which allows the MCU 32 to enable and disable operation of the first switching circuit 34, and
a ground terminal (labelled “GND”) electrically connected to ground.

The select signals from the second and third input/output terminals of the MCU 32 to the pair of select terminal (labelled “S0” and “S1”) of the first switching circuit 34 may be low or high. In FIG. 2, the select signal from the second input/output terminal of the MCU 32 to the select terminal S0 is labelled “SELECTS0_SPTT1” and the select signal from the third input/output terminal of the MCU 32 to the select terminal S1 is labelled “SELECTS1_SPTT1”. The possible connections between the input terminals Y0, Y1 and Y2, and the output terminal Z are shown in Table 1 below:

TABLE 1

| SELECTS0_SPTT1 | SELECTS1_SPTT1 | Connection |
|---|---|---|
| Low | Low | Y0 - Z |
| High | Low | Y1 - Z |
| Low | High | Y2 - Z |
| High | High | Y0, Y1, Y2 - Z |
| | | (broadcast mode) |

For example, it may be seen that if the select signals SELECTS0_SPTT1 and SELECTS1_SPTT1 are both low, the first input terminal Y0 is electrically connected to the output terminal Z. In this case, the output terminal Z may receive DC current either from the battery terminal of the charging circuit 22 or from the first energy storage device 14 if the first semiconductor switch Q1 is switched on. It may be seen that if the select signal SELECTS0_SPTT1 is high and the select signal SELECTS1_SPTT1 is low, the second input terminal Y1 is electrically connected to the output terminal Z. In this case, the output terminal Z may receive DC current from either the capacitor terminal of the reversible buck/boost regulator 30 or from the second energy storage device 16 if the second semiconductor switch Q2 is switched on.

It may be seen that if the select signal SELECTS0_SPTT1 is low and the select signal SELECTS1_SPTT1 is high, the third input terminal Y2 is electrically connected to the output terminal Z. In this case, the output terminal Z may receive DC current from the system bus 48—i.e., from the system terminal of the charging circuit 22. The first switching circuit 34 is therefore used to select an appropriate power source for the superimposing circuit 42 as described in more detail below. It may be seen that if the select signals SELECTS0_SPTT1 and SELECTS1_SPTT1 are both high, the first input terminal Y0, the second input terminal YT, and the third input terminal Y2 are electrically connected to the output terminal Z at the same time. Such connection is normally referred to as a broadcast mode.

The DC/DC converter 24 typically operates as a boost (or step-up) converter and converts a DC input voltage into a suitable boosted DC output voltage. The DC/DC converter 24 includes:
a voltage input terminal (labelled “VIN”) electrically connected to the output terminal of the first switching circuit 34,
a switching node terminal (labelled “SW”) electrically connected to the voltage input terminal by means of an inductor,
a voltage output terminal (labelled “VOUT”) electrically connected to the induction heater 50 (or other suitable aerosol generator) by means of a third semiconductor switch Q3,
a ground terminal (labelled “GND”) electrically connected to ground,
a serial data terminal (labelled “SDA”) and a serial clock terminal (labelled “SCL”) that are electrically connected to corresponding terminals of the MCU 32,
a feedback terminal (labelled “FB”) which receives a DC output voltage feedback, and
an enable terminal (labelled “EN”) electrically connected to a fifth input/output terminal (labelled “I/O”) of the MCU 32 and which allows the MCU 32 to enable and disable operation of the first DC/DC converter 24.

The voltage input and output terminals of the DC/DC converter 24 are electrically connected by a bypass circuit 52 that includes a fourth semiconductor switch Q4.

The reversible buck/boost regulator 30 may operate in a buck (or step-down) mode or a boost (or step-up) mode. When the system voltage (labelled “Vsys”) on the system bus 48 is above a minimum operating voltage, the reversible buck/boost regulator 30 will typically operate in a buck mode to charge the second energy storage device 16 from the system bus 48 until it is fully charged. If the voltage on the system bus 48 is removed, the reversible buck/boost regulator 30 typically operates in a boost mode and prevents the system voltage from dropping below the minimum operating voltage by discharging the second energy storage device 16 to the system bus 48. The reversible buck/boost regulator 30 includes:
a capacitor terminal (labelled “CAP”) electrically connected to the positive terminal of the second energy storage device 16, i.e., the capacitor module, by means of the second semiconductor switch Q2, and to the second input terminal Y1 of the first switching circuit 34,
a switching node terminal (labelled “LX”) electrically connected to the second semiconductor switch Q2 by means of an inductor,
a system terminal (labelled “SYS”) electrically connected to the system bus 48,
a ground terminal (labelled “GND”) electrically connected to ground,
a pair of feedback terminals (labelled “FB1” and “FB2”) that receive respective DC input and output voltage feedbacks,
a current input terminal labelled (“ISET”) that sets the peak discharge and discharging currents of the reversible buck/boost regulator 30, and
an enable terminal (labelled “EN”) electrically connected to a sixth input/output terminal (labelled “I/O”) of the MCU 32 and which allows the MCU 32 to enable and disable operation of the reversible buck/boost regulator 30.

The second switching circuit 36 is a single-pole triple-throw (SPTT) switch and includes:
a first input terminal (labelled “Y0”) electrically connected to the output terminal of the first switching circuit 34,
a second input terminal (labelled “YT”) electrically connected to the positive terminal of the first energy storage device 14,
a third input terminal (labelled “Y2”) electrically connected to the positive terminal of the second energy storage device 16,
an output terminal (labelled “Z”),
a pair of select terminals (labelled “S0” and “S1”) respectively electrically connected to seventh and eighth input/output terminals (labelled “I/O”) of the MCU 32 and which allow the MCU 32 to selectively control which input terminal is connected to the output terminal by means of two select signals—i.e., to select if the output terminal is electrically connected to: (i) the output terminal Z of the first switching circuit 34 by means of the first input terminal Y0, (ii) the positive terminal of the first energy storage device 14 by means of the second input terminal YT, or (iii) the positive terminal of the second energy storage device 16 by means of the second input terminal Y2,
a power supply terminal (labelled “VDD”) electrically connected to the voltage output terminal of the LDO regulator 28 and receives a regulated voltage supply
see below,
an enable terminal (labelled “EN”) electrically connected to a ninth input/output terminal (labelled “I/O”) of the MCU 32 and which allows the MCU 32 to enable and disable operation of the second switching circuit 36, and
a ground terminal (labelled “GND”) electrically connected to ground.

The select signals from the seventh and eighth input/output terminals of the MCU 32 to the pair of select terminal (labelled “S0” and “S1”) of the second switching circuit 36 may be low or high. In FIG. 2, the select signal from the seventh input/output terminal of the MCU 32 to the select terminal S0 is labelled “SELECTS0_SPTT2” and the select signal from the eighth input/output terminal of the MCU 32 to the select terminal S1 is labelled “SELECTS1_SPTT2”. The possible connections between the input terminals Y0, Y1 and Y2, and the output terminal Z are shown in Table 2 below:

TABLE 2

| SELECTS0_SPTT2 | SELECTS1_SPTT2 | Connection |
|---|---|---|
| Low | Low | Y0 - Z |
| High | Low | Y1 - Z |
| Low | High | Y2 - Z |
| High | High | Y0, Y1, Y2 - Z |
| | | (broadcast mode) |

For example, it may be seen that if the select signals SELECTS0_SPTT2 and SELECTS1_SPTT2 are both low, the first input terminal Y0 is electrically connected to the output terminal Z. In this case, the output terminal Z may receive DC current from the output terminal of the first switching circuit 34. It may be seen that if the select signal SELECTS0_SPTT2 is high and the select signal SELECTS1_SPTT2 is low, the second input terminal Y1 is electrically connected to the output terminal Z. In this case, the output terminal Z may receive DC current from the first energy storage device 14.

It may be seen that if the select signal SELECTS0-SPTT2 is low and the select signal SELECTS1_SPTT2 is high, the third input terminal Y2 is electrically connected to the output terminal Z. In this case, the output terminal Z may receive DC current from the second energy storage device 16. The second switching circuit 36 is therefore used to select an appropriate power source for the inverter 26 as described in more detail below.

Like for the first switching circuit 34, it may be seen that if the select signals SELECTS0_SPTT2 and SELECTS1_SPTT2 are both high, the first input terminal Y0, the second input terminal Y1, and the third input terminal Y2 are electrically connected to the output terminal Z at the same time.

The inverter 26 includes:
a positive input terminal (labelled “IN+”) electrically connected to the output terminal of the second switching circuit 36,
a positive output terminal (labelled “OUT+”) and a negative output terminal (labelled “OUT−”),
a serial data terminal (labelled “SDA”) and a serial clock terminal (labelled “SCL”) that are electrically connected to corresponding terminals of the MCU 32, and
an enable terminal (labelled “EN”) electrically connected to a tenth input/output terminal (labelled “I/O”) of the MCU 32 and which allows the MCU 32 to enable and disable operation of the inverter 26.

When enabled, the inverter 26 may provide an AC signal at the positive output terminal. The AC signal has a suitable waveform with a frequency that is determined by the MCU 32. The MCU 32 may control the AC signal by means of serial data communication with the inverter 26. The waveform may be sinusoidal or square, for example, and depending on the waveform used band pass filtering of the voltage and current measurements may be preferred. In this embodiment, the frequency of the AC signal may be about 1 kHz, for example. But in other embodiments, the frequency may be in the range of about 100 Hz to about 3 kHz, for example. The amplitude of the AC signal should preferably not cause higher overvoltage than about 5-10 mV (for 500 mΩ internal impedance and 0.1-0.02 A maximum peak current).

In addition to the positive input terminal, the invertor 26 may include a negative input terminal not shown in FIG. 2. Alternatively, the negative output terminal may also be used as a negative input terminal.

The LDO regulator 28 includes:
an input terminal (labelled “IN”) electrically connected to the system bus 48,
an output terminal (labelled “OUT”) that provides a regulated voltage supply,
a ground terminal (labelled “GND”) electrically connected to ground, and
an enable terminal (labelled “EN”) electrically connected to the system bus 48.

In this embodiment, the enable terminal of the LDO regulator 28 works according to positive logic and the input and enable terminals of the LDO regulator are electrically connected to the system bus 48 in parallel. This means that the LDO regulator 28 continuously outputs a regulated voltage from the output terminal unless the system bus voltage is unavailable. The enable terminals of the charging circuit 22, DC/DC converter 24, inverter 26, reversible buck/boost regulator 30, first switching circuit 34, and second switching circuit 36 may use positive or negative logic. The regulated output voltage of the LDO regulator 28 is labelled “VMcu”.

The MCU 32 includes a power supply terminal (labelled “VDD”) electrically connected to the voltage output terminal of the LDO regulator 28 and receives a regulated voltage supply. As noted above, the MCU 32 includes a serial data terminal (labelled “SDA”) and a serial clock terminal (labelled “SCL”) that are electrically connected to corresponding terminals of the charging circuit 22, DC/DC converter 24, and inverter 26. The MCU 32 also includes:
a ground terminal (labelled “GND”) electrically connected to ground,
first, fourth, fifth, sixth, ninth and tenth input/output terminals (labelled “I/O”) that are respectively electrically connected to the enable terminals of the charging circuit 22, first switching circuit 34, the DC/DC converter 24, the reversible buck/boost regulator 30, the second switching circuit 36, and the inverter 26,
second and third input/output terminals (labelled “I/O”) that are respectively electrically connected to the pair of select terminals S0, S1 of the first switching circuit 34,
seventh and eighth input/output terminals (labelled “I/O”) that are respectively electrically connected to the pair of select terminals S0, S1 of the second switching circuit 36, and
eleventh, twelfth, thirteenth and fourteenth input/output terminals (labelled “I/O”) that are respectively electrically connected to the first, second, third and fourth semiconductor switches Q1, Q2, Q3 and Q4 for switching them on and off.

When the first semiconductor switch Q1 is switched on, DC current may be supplied from the battery terminal of the charging circuit 22 to the positive terminal of the first energy storage device 14 if the voltage of the external power source is available. When the first semiconductor switch Q1 is switched off, the first input terminal Y0 of the first switching circuit 34 remains electrically connected to the battery terminal of the charging circuit 22 so that DC current may be supplied from the battery terminal to the first switching circuit 34. The first semiconductor switch Q1 may be a metal-oxide semiconductor field-effect transistor (MOSFET) that includes an intrinsic body diode. The anode of the body diode is electrically connected to the positive terminal of the first energy storage device 14 and the cathode is electrically connected to the battery terminal of the charging circuit 22. This means that the first energy storage device 14 may continuously supply power to the battery terminal of the charging circuit 22 even if the first semiconductor switch Q1 is switched off In the case of other types of semiconductor switches, an anti-parallel diode may be provided, for example.

When the second semiconductor switch Q2 is switched on, DC current may be supplied from the capacitor terminal of the reversible buck/boost regulator 30 to the positive terminal of the second energy storage device 16 if the system bus voltage is available. When the second semiconductor switch Q2 is switched off, the second input terminal Y1 of the first switching circuit 34 remains electrically connected to the capacitor terminal of the reversible buck/boost regulator 30 so that DC current may be supplied from the capacitor terminal to the first switching circuit 34. The second semiconductor switch Q2 may be a MOSFET that includes an intrinsic body diode. The anode of the body diode is electrically connected to the positive terminal of the second energy storage device 16 and the cathode is electrically connected to the capacitor terminal of the reversible buck/boost regulator 30. This means that the second energy storage device 16 may continuously supply power to the capacitor terminal of the reversible buck/boost regulator 30 even if the second semiconductor switch Q2 is switched off. In the case of other types of semiconductor switches, an anti-parallel diode may be provided, for example.

When the third semiconductor switch Q3 is switched on, the voltage output terminal of the DC/DC converter 24 is electrically connected to the induction heater 50 (or another suitable aerosol generator). When the third semiconductor switch Q3 is switched off, the induction heater 50 is electrically isolated from the voltage output terminal of the DC/DC converter 24 and the output of the bypass circuit 52. The induction heater 50 may be electrically isolated when heating is not required, e.g., during a non-heating mode of the aerosol generating device 2. The MCU 32 may control an operation of the inductor heater 50 by controlling the switching of the third semiconductor switch Q3 using any suitable control algorithm, e.g., pulse width modulation (PWM) or pulse frequency modulation (PFM).

When the fourth semiconductor switch Q4 is switched on, the voltage input and output terminals of the DC/DC converter 24 are electrically connected through the bypass circuit 52. This allows DC current to be supplied from the output terminal Z of the first switching circuit 34 directly to the superimposing circuit 42, effectively bypassing the disabled DC/DC converter 24. If the DC/DC converter 24 may be operated using a direct connection mode where the DC/DC converter 24 outputs a voltage from the voltage output terminal that is substantially the same as the voltage supplied to the voltage input terminal, the fourth semiconductor switch Q4 and the bypass circuit 52 may be omitted.

The positive voltage output terminal of the inverter 26 is electrically connected to the superimposing circuit 42. The superimposing circuit 42 is configured to superimpose the AC signal from the inverter 26 on DC current supplied by the DC/DC converter 24 or through the bypass circuit 52. The superimposing circuit 42 includes an operational amplifier 54. The operational amplifier 54 includes:
a non-inverting input terminal (labelled “+”) electrically connected to the voltage output terminal of the DC/DC converter 24 and the output of the bypass circuit 52 by means of a first resistor R1, and to a ground connection of the superimposing circuit 42 by means of a first capacitor C1 and a parallel second resistor R2, and
an inverting input terminal (labelled “−”) electrically connected to the positive voltage output terminal of the inverter 26,
a positive voltage terminal electrically connected to the voltage output terminal of the DC/DC converter 28 and the output of the bypass circuit 52 in parallel with the non-inverting input terminal of the operational amplifier 54,
a negative voltage terminal electrically connected to the ground connection of the superimposing circuit 42, and
a voltage output terminal.

A junction point 56 between the inverting input terminal of the operational amplifier 54 and the positive output terminal of the inverter 26 is electrically connected to the voltage output terminal of the operational amplifier 54 by means of a third resistor R3 and to the ground connection by means of a fourth resistor R4. The negative output terminal of the inverter 26 is also electrically connected to the ground connection of the superimposing circuit 42. The output voltage at the voltage output terminal of the operational amplifier 54 has AC and DC components.

The third switching circuit 38 is a single-pole double-throw (SPDT) switch and includes:
an input terminal (labelled “Y”) electrically connected to the voltage output terminal of the operational amplifier 54,
a first output terminal (labelled “Z1”) electrically connected to the positive terminal of the first energy storage device 14,
a second output terminal (labelled “Z2”) electrically connected to the positive terminal of the second energy storage device 16,
a select terminal (labelled “SEL”) electrically connected to a fifteenth input/output terminal (labelled “I/O”) of the MCU 32 and which allows the MCU 32 to selectively control which output terminal is connected to the input terminal by means of a select signal—i.e., to select if the voltage output terminal of the operational amplifier 54 is electrically connected to the first energy storage device 14 by means of the first output terminal Z1, or the second energy storage device 16 by means of the second output terminal Z2,
a power supply terminal (labelled “VDD”) electrically connected to the voltage output terminal of the LDO regulator 28 and receives a regulated voltage supply, and
a ground terminal (labelled “GND”) electrically connected to ground.

The voltage sensing circuit 44 is electrically connected to a junction point 58 between the voltage output terminal of the operational amplifier 54 and the input terminal of the third switching circuit 38 and is configured to detect the voltage across one of the first and second energy storage devices 14, 16 when the AC signal is applied. A sixteenth input/output terminal (labelled “I/O”) of the MCU 32 is electrically connected to the voltage sensing circuit 44, optionally by means of an AC coupling capacitor C2. An additional voltage sensing circuit 60 is configured to detect the input voltage V_{BUS} from the external power source (not shown). A seventeenth input/output terminal (labelled “I/O”) of the MCU 32 is electrically connected to the additional voltage sensing circuit 60.

The current sensing circuit 46 includes a shunt resistor R5 and a current sensing amplifier 62 electrically connected with the shunt resistor. The shunt resistor R5 is electrically connected to a ground connection of the current sensing circuit 46. An eighteenth input/output terminal (labelled “I/O”) of the MCU 32 is electrically connected to the current sensing amplifier 62 of the current sensing circuit 46, optionally by means of an AC coupling capacitor C3. An additional operational amplifier 64 may be provided to improve accuracy of the current measurement by stabilising the electrical ground potential.

Each fourth switching circuit 40A, 40B is a single-pole double-throw (SPDT) switch. One of the fourth switching circuits 40A includes:
an input terminal (labelled “Y”) electrically connected to the negative terminal of the first energy storage device 14,
a first output terminal (labelled “Z1”) electrically connected to the shunt resistor R5 of the current sensing circuit 46,
a second output terminal (labelled “Z2”) electrically connected to the ground connection of the current sensing circuit 46,
a select terminal (labelled “SEL”) electrically connected to the fifteenth input/output terminal (labelled “I/O”) of the MCU 32 and which allows the MCU to selectively control which output terminal is connected to the input terminal—i.e., to select if the negative terminal of the first energy storage device 14 is electrically connected to the shunt resistor R5 by means of the first output terminal Z1, or directly to the ground connection of the current sensing circuit 46 by means of the second output terminal Z2,
a power supply terminal (labelled “VDD”) electrically connected to the voltage output terminal of the LDO regulator 28 and receives a regulated voltage supply, and
a ground terminal (labelled “GND”) electrically connected to ground.

The other one of the fourth switching circuits 40B includes:
an input terminal (labelled “Y”) electrically connected to the negative terminal of the second energy storage device 16,
a first output terminal (labelled “Z1”) electrically connected to the ground connection of the current sensing circuit 46,
a second output terminal (labelled “Z2”) electrically connected to the shunt resistor R5 of the current sensing circuit 46,
a select terminal (labelled “SEL”) electrically connected to the fifteenth input/output terminal (labelled “I/O”) of the MCU 32 and which allows the MCU to selectively control which output terminal is connected to the input terminal—i.e., to select if the negative terminal of the second energy storage device 16 is electrically connected to the shunt resistor R5 by means of the second output terminal Z2, or directly to the ground connection of the current sensing circuit 46 by means of the first output terminal Z1,
a power supply terminal (labelled “VDD”) electrically connected to the voltage output terminal of the LDO regulator 28 and that receives a regulated voltage supply, and
a ground terminal (labelled “GND”) electrically connected to ground.

The select signal from the fifteenth input/output terminal of the MCU 32 to the select terminals of the third switching circuit 38 and the pair of fourth switching circuits 40A, 50B (labelled “SELECT_AC_PATH”) may be low or high. If the select signal is low, the input terminal Y of each switching circuit 38, 40A and 40B is connected to the first output terminal Z1, and if the select signal is high, the input terminal Y of each switching circuit 38, 40A and 40B is connected to the second output terminal Z2. In practice, this means that if the select signal is low:
the voltage output terminal of the operational amplifier 54 of the superimposing circuit 42 is electrically connected to the positive terminal of the first energy storage device 14 through the third switching circuit 38,
the negative terminal of the first energy storage device 14 is electrically connected to the shunt resistor R5 of the current sensing circuit 46 through the corresponding one of the fourth switching circuits 40A, and
the negative terminal of the second energy storage device 16 is electrically connected directly to the ground connection of the current sensing circuit 46 through the other corresponding one of the fourth switching circuits 40B. This circuit configuration allows the AC signal to be applied to the first energy storage device 14 while it is being charged i.e., where the output voltage of the operational amplifier 54 of the superimposing circuit 42 with AC and DC components is provided to the positive terminal of the first energy storage device 14.

If the select signal is high:
the voltage output terminal of the operational amplifier 54 of the superimposing circuit 42 is electrically connected to the positive terminal of the second energy storage device 16 through the third switching circuit 38,
the negative terminal of the first energy storage device 14 is electrically connected directly to the ground connection of the current sensing circuit 46 through the corresponding one of the fourth switching circuits 40A, and
the negative terminal of the second energy storage device 16 is electrically connected to the shunt resistor R5 of the current sensing circuit 46 through the other corresponding one of the fourth switching circuits 40B. This circuit device 16 while it is being charged, i.e., where the output voltage of the operational amplifier 54 of the superimposing circuit 42 with AC and DC components is provided to the positive terminal of the second energy storage device 16.

A temperature sensor (e.g., a thermocouple or thermistor) 66 is positioned on an outer surface of the first energy storage device 14 and is configured to detect its surface temperature. The temperature sensor 66 is electrically connected to a nineteenth input/output terminal (labelled “I/O”) of the MCU 32.

The signals labelled in FIG. 2 are summarised in Table 3 below:

TABLE 3

| | I/O | |
|---|---|---|
| Signal | Terminal | Description |
| nENABLE_CHARGING | 1 | Enable/disable signal for the |
| | | charging circuit 22 |
| SELECTS0_SPTT1 | 2 | Select signals for the first |
| SELECTS1_SPTT1 | 3 | switching circuit 34 |
| nENABLE_SPTT1 | 4 | Enable/disable signal for the |
| | | first switching circuit 34 |
| ENABLE_CONVERTER | 5 | Enable/disable signal for the |
| | | DC/DC converter 24 |
| ENABLE_REGULATOR | 6 | Enable/disable signal for the |
| | | reversible buck/boost |
| | | regulator 30 |
| SELECTS0_SPTT2 | 7 | Select signals for the second |
| SELECTS1_SPTT2 | 8 | switching circuit 36 |
| nENABLE_SPTT2 | 9 | Enable/disable signal for the |
| | | second switching circuit 36 |
| ENABLE_INVERTER | 10 | Enable/disable signal for the |
| | | inverter 26 |
| ENABLE_ES1 | 11 | Enable/disable signal for the |
| | | first semiconductor switch Q1 |
| ENABLE_ES2 | 12 | Enable/disable signal for the |
| | | second semiconductor switch |
| | | Q2 |
| nENABLE_HEATER | 13 | Enable/disable signal for the |
| | | third semiconductor switch |
| | | Q3 |
| nBYPASS_CONVERTER | 14 | Enable/disable signal for the |
| | | fourth semiconductor switch |
| | | Q4 |
| SELECT_AC_PATH | 15 | Select signal for the third and |
| | | fourth switching circuits 38, |
| | | 40A and 40B |
| MONITOR_AC_VOLTAGE | 16 | Input signal from the voltage |
| | | sensing circuit 44 |
| DETECT_VBUS | 17 | Input signal from the voltage |
| | | sensing circuit 60 |
| MONITOR_AC_CURRENT | 18 | Input signal from the current |
| | | sensing circuit 46 |
| MONITOR_TEMP | 19 | Input signal from the |
| | | temperature sensor 66 |

Enable signals with the prefix “ENABLE_” may use positive logic and enable signals with the prefix “nENABLE_” may use negative logic. For example, charging of the first energy storage device 14 from the external power source is enabled if the enable signal nENABLE_CHARGING for the charging circuit 22 is low and operation of the reversible buck/boost regulator 30 is enabled if the enable signal ENABLE_REGULATOR is high. The enable signals ENABLE_ES1 and ENABLE_ES2 are enable signals for monitoring the condition of the first and second energy storage devices 14, 16, respectively.

An I²C communication protocol may be used for serial data communication between the MCU 32 and the charging circuit 22, DC/DC converter 24, and inverter 26. Other suitable communication protocols such as SPI or UART may be also used.

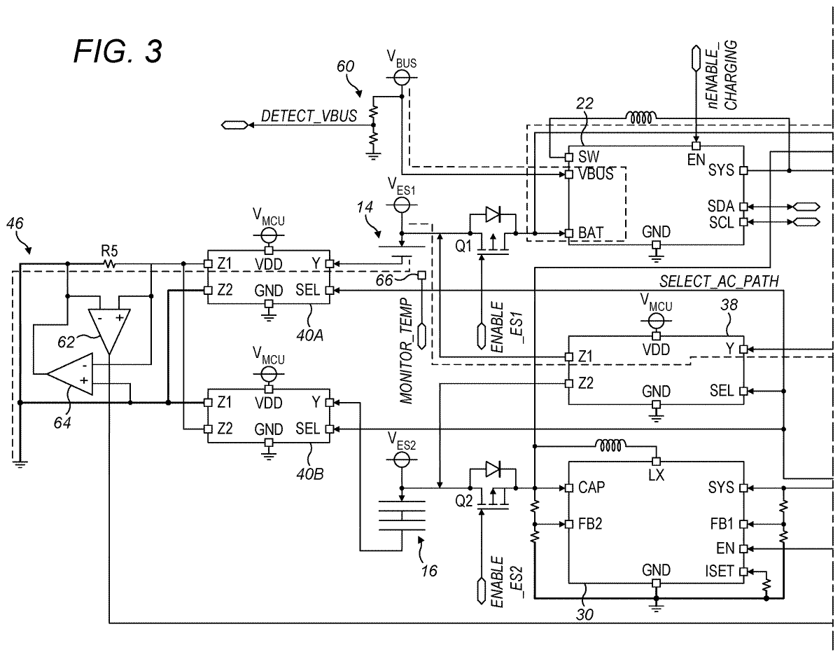

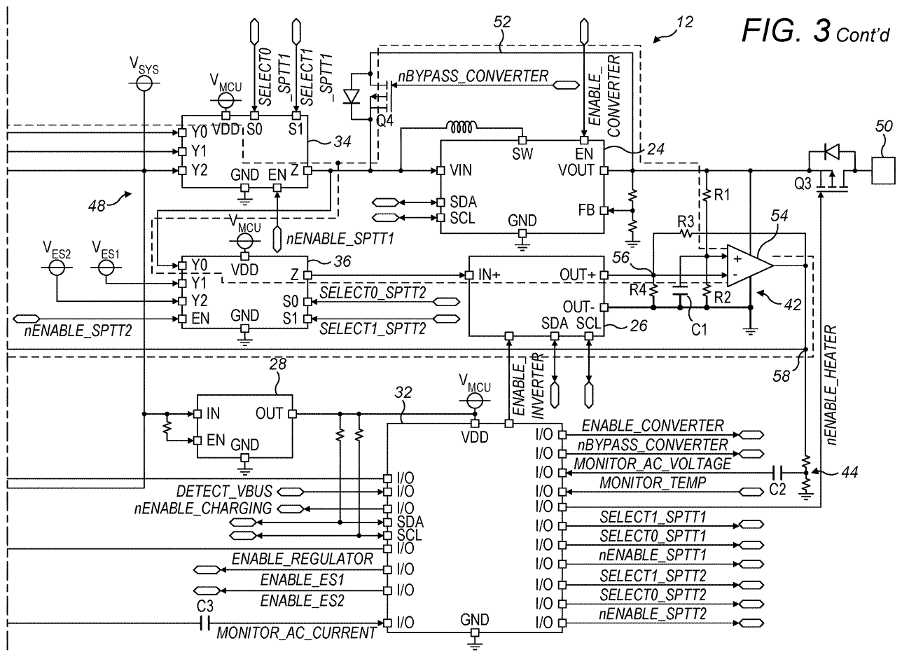

FIG. 3 shows a first method of monitoring a condition of the first energy storage device 14 when it is being charged by an external power source (e.g., a USB charger) that is electrically connected to the input terminal of the charging circuit 22. The external power source may be detected by the additional voltage sensing circuit 60, i.e., using the signal DETECT_VBUS that is provided to the MCU 32. The signal DETECT_VBUS turns high once the external power source is connected.

The first semiconductor switch Q1 is switched off by the MCU 32 by sending the enable signal ENABLE_ES1 with a high level from the eleventh input/output terminal.

The charging circuit 22 is enabled. More particularly, the MCU 32 sends a enable signal (i.e., nENABLE_CHARGING with a low level) from the first input/output terminal to the enable terminal of the charging circuit 22.

The DC/DC converter 24 is disabled. More particularly, the MCU 32 sends a disable signal (i.e., ENABLE_CONVERTER with a low level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is disabled. More particularly, the MCU 32 sends a disable signal (i.e., ENABLE_REGULATOR with a low level) from the sixth input/output terminal to the enable terminal of the reversible buck/boost regulator 30.

The first switching circuit 34 is enabled. More particularly, the MCU 32 sends an enable signal (i.e., nENABLE_SPTT1 with a low level) from the fourth input/output terminal to the enable terminal of the first switching circuit 34. The MCU 32 also sends the select signals SELECTS0_SPTT1 and SELECTS1_SPTT1 from the second and third input/output terminals to the select terminals S0, S1 of the first switching circuit 34.

The select signals SELECTS0_SPTT1 and SELECTS1_SPTT1 are both low and so the first input terminal Y0 is connected to the output terminal Z.

The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signals SELECTS0_SPTT2 and SELECTS1_SPTT2 are both low and so the first input terminal Y0 is connected to the output terminal Z.

The third semiconductor switch Q3 is switched off to electrically disconnect the induction heater 50 from the DC/DC converter 24 and the output of the bypass circuit 52. More particularly, the MCU 32 sends a disable signal (i.e., nENABLE_HEATER with a high level) from the thirteenth input/output terminal.

The fourth semiconductor switch Q4 is switched on to bypass the disabled DC/DC converter 24—i.e., so that the voltage input and output terminals are electrically connected through the bypass circuit 52. More particularly, the MCU 32 sends an enable signal (i.e., nBYPASS_CONVERTER with a low level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is low so that the input terminals Y are connected to the respective first output terminal Z1.

A DC charging current from the external power source is supplied to the input terminal of the charging circuit 22. The DC current is supplied from the battery terminal of the charging circuit 22 to the first input terminal Y0 of the first switching circuit 34, which is connected to the output terminal Z. From the output terminal Z of the first switching circuit 34, the DC current is supplied to the non-inverting input terminal of the operational amplifier 54 of the superimposing circuit 42 through the bypass circuit 52.

At the same time, the DC current is supplied from the output terminal Z of the first switching circuit 34 to the first input terminal Y0 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components.

In this embodiment, both the inverter 26 and the non-inverting input terminal of the operational amplifier 54 receive DC current from the external power source.

The select signal SELECT_AC_PATH from the fifteenth input/output terminal of the MCU 32 to the select terminals of the third switching circuit 38 and the pair of fourth switching circuits 40A, 40B is low so that the output voltage of the operational amplifier 54 is provided to the positive terminal of the first energy storage device 14 to charge it. The negative terminal of the first energy storage device 14 is electrically connected to the shunt resistor R5 of the current sensing circuit 46. While the first energy storage device 14 is being charged, voltage and current measurements are detected by the voltage and current sensing circuits 44, 46 and provided to the MCU 32—i.e., to the sixteenth and eighteenth input/output terminals of the MCU 32.

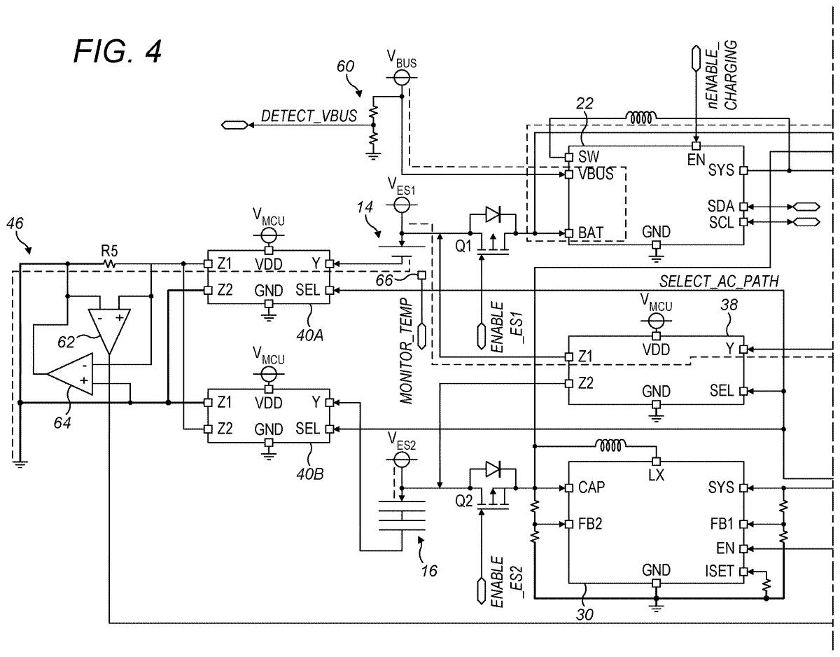

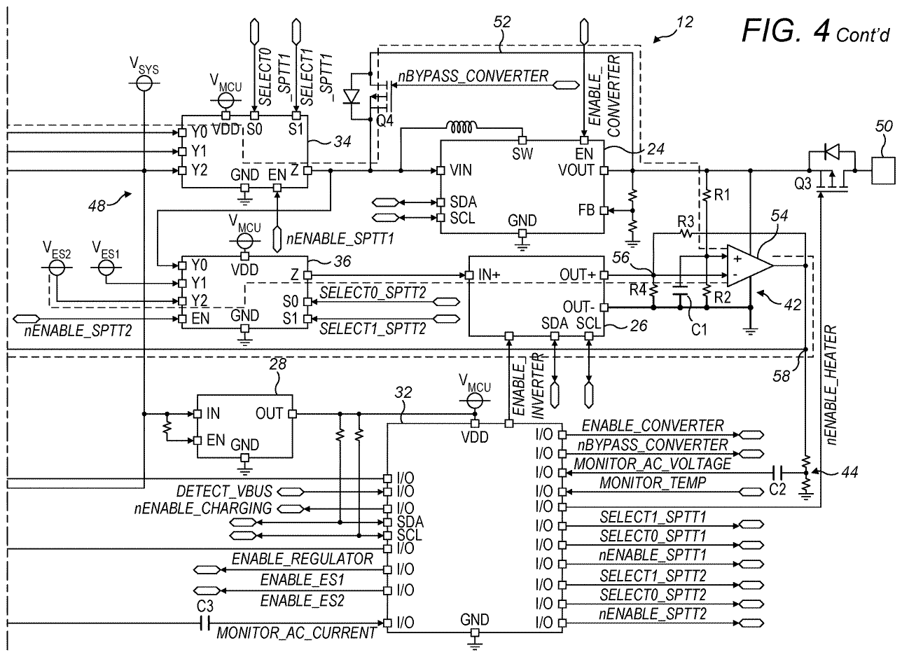

FIG. 4 shows a second method of monitoring a condition of the first energy storage device 14 when it is being charged by an external power source (e.g., a USB charger) that is electrically connected to the input terminal of the charging circuit 22. The external power source may be detected by the additional voltage sensing circuit 60, i.e., using the signal DETECT_VBUS that is provided to the MCU 32. The signal DETECT_VBUS turns high once the external power source is connected.

The first semiconductor switch Q1 is switched off by the MCU 32 by sending the enable signal ENABLE_ES1 with a high level from the eleventh input/output terminal.

The charging circuit 22 is enabled. More particularly, the MCU 32 sends a enable signal (i.e., nENABLE_CHARGING with a low level) from the first input/output terminal to the enable terminal of the charging circuit 22.

The DC/DC converter 24 is disabled. More particularly, the MCU 32 sends a disable signal (i.e., ENABLE_CONVERTER with a low level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is disabled. More particularly, the MCU 32 sends a disable signal (i.e., ENABLE_REGULATOR with a low level) from the sixth input/output terminal to the enable terminal of the reversible buck/boost regulator 30. The first switching circuit 34 is enabled. More particularly, the MCU 32 sends an enable signal (i.e., nENABLE_SPTT1 with a low level) from the fourth input/output terminal to the enable terminal of the first switching circuit 34. The MCU 32 also sends the select signals SELECTS0_SPTT1 and SELECTS1_SPTT1 from the second and third input/output terminals to the select terminals S0, S1 of the first switching circuit 34.

The select signals SELECTS0_SPTT1 and SELECTS1_SPTT1 are both low and so the first input terminal Y0 is connected to the output terminal Z.

The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signal SELECTS0_SPTT2 is low and the select signal SELECTS1_SPTT2 is high and so the third input terminal Y2 is connected to the output terminal Z.

The third semiconductor switch Q3 is switched off to electrically disconnect the induction heater 50 from the DC/DC converter 24 and the output of the bypass circuit 52. More particularly, the MCU 32 sends a disable signal (i.e., nENABLE_HEATER with a high level) from the thirteenth input/output terminal.

The fourth semiconductor switch Q4 is switched on to bypass the disabled DC/DC converter 24—i.e., so that the voltage input and output terminals are electrically connected through the bypass circuit 52. More particularly, the MCU 32 sends an enable signal (i.e., nBYPASS_CONVERTER with a low level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is low so that the input terminals Y are connected to the respective first output terminal Z1. A DC charging current from the external power source is supplied to the input terminal of the charging circuit 22. The DC current is supplied from the battery terminal of the charging circuit 22 to the first input terminal Y0 of the first switching circuit 34, which is connected to the output terminal Z. From the output terminal Z of the first switching circuit 34, the DC current is supplied to the non-inverting input terminal of the operational amplifier 54 of the superimposing circuit 42 through the bypass circuit 52.

DC current is supplied from the positive terminal of the second energy storage device 16 to the third output terminal Y2 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components. In this embodiment, the inverter 26 receives DC current from the second energy storage device 16 and the non-inverting input terminal of the operational amplifier 54 receives DC current from the external power source.

Compared with the first method shown in FIG. 3, a charging speed of the first energy storage device 14 may be improved because the DC current from the external power source is intensively supplied to the first energy storage device 14.

The select signal SELECT_AC_PATH from the fifteenth input/output terminal of the MCU 32 to the select terminals of the third switching circuit 38 and the pair of fourth switching circuits 40A, 40B is low so that the output voltage of the operational amplifier 54 is provided to the positive terminal of the first energy storage device 14 to charge it. The negative terminal of the first energy storage device 14 is electrically connected to the shunt resistor R5 of the current sensing circuit 46. While the first energy storage device 14 is being charged, voltage and current measurements are detected by the voltage and current sensing circuits 44, 46 and provided to the MCU 32—i.e., to the sixteenth and eighteenth input/output terminals of the MCU 32.

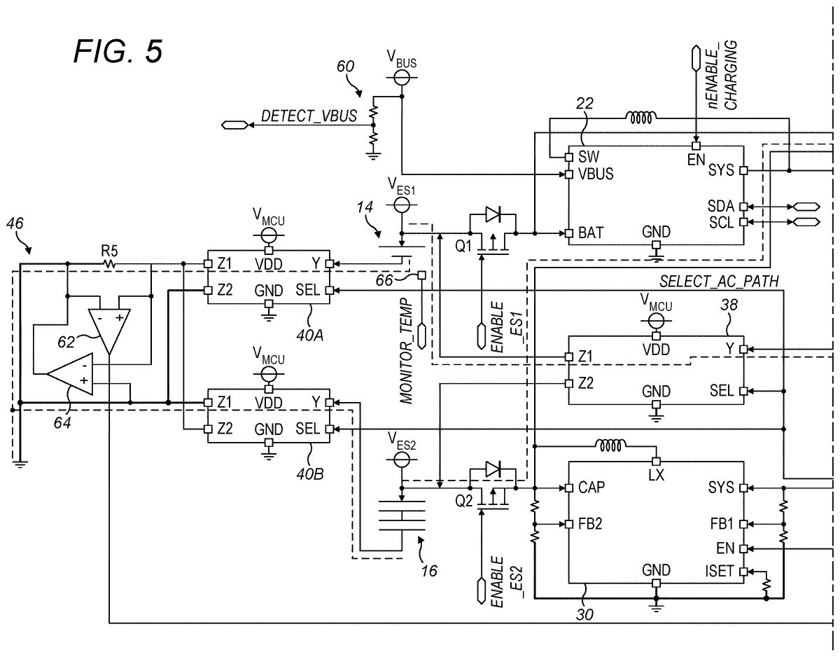

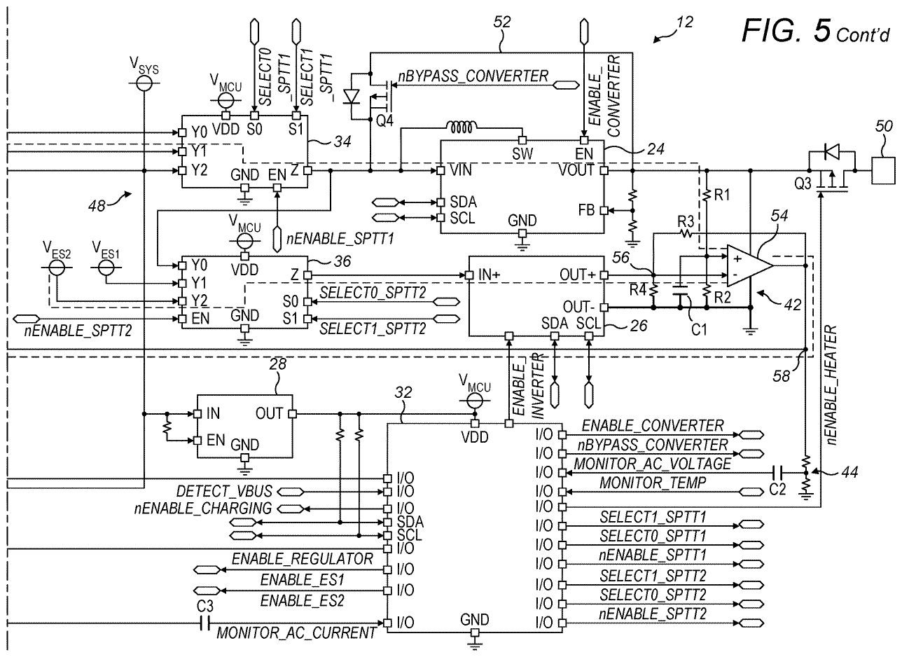

FIG. 5 shows a third method of monitoring a condition of the first energy storage device 14 when it is being charged by the second energy storage device 16.

The first semiconductor switch Q1 is switched off by the MCU 32 by sending the enable signal ENABLE_ES1 with a high level from the eleventh input/output terminal.

The charging circuit 22 is disabled. More particularly, the MCU 32 sends a disable signal (i.e., nENABLE_CHARGING with a high level) from the first input/output terminal to the enable terminal of the charging circuit 22.

The DC/DC converter 24 is enabled. More particularly, the MCU 32 sends an enable signal (i.e., ENABLE_CONVERTER with a high level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is disabled. More particularly, the MCU 32 sends a disable signal (i.e., ENABLE_REGULATOR with a low level) from the sixth input/output terminal to the enable terminal of the reversible buck/boost regulator 30.

The first switching circuit 34 is enabled. More particularly, the MCU 32 sends an enable signal (i.e., nENABLE_SPTT1 with a low level) from the fourth input/output terminal to the enable terminal of the first switching circuit 34. The MCU 32 also sends the select signals SELECTS0_SPTT1 and SELECTS1_SPTT1 from the second and third input/output terminals to the select terminal S0, S1 of the first switching circuit 34. The select signal SELECTS0_SPTT1 is high and the select signal SELECTS1_SPTT1 is low and so the second input terminal Y1 is connected to the output terminal Z. The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signal SELECTS0_SPTT2 is low and the select signal SELECTS1_SPTT2 is high and so the third input terminal Y2 is connected to the output terminal Z.

The third semiconductor switch Q3 is switched off to electrically disconnect the induction heater 50 from the DC/DC converter 24. More particularly, the MCU 32 sends a disable signal (i.e., nENABLE_HEATER with a high level) from the thirteenth input/output terminal.

The fourth semiconductor switch Q4 is switched off. More particularly, the MCU 32 sends a disable signal (i.e., nBYPASS_CONVERTER with a high level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is low so that the input terminals Y are connected to the respective first output terminal Z1.

A DC charging current from the second energy storage device 16 is supplied to the second input terminal Y1 of the first switching circuit 34, which is connected to the output terminal Z. In particular the DC current flows through the body diode of the second semiconductor switch Q2. From the output terminal Z of the first switching circuit 34, the DC current is supplied to the voltage input terminal of the DC/DC converter 24. A boosted DC current is supplied from the volage output terminal of the DC/DC converter 24 to the non-inverting input terminal of the operational amplifier 54 of the superimposing circuit 42.

DC current is also supplied from the positive terminal of the second energy storage device 16 to the third output terminal Y2 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components. In this embodiment, both the inverter 26 and the non-inverting input terminal of the operational amplifier 54 receive DC current from the second energy storage device 16.

This method allows a condition of the first energy storage device 14 to be monitored without an external power supply.

The select signal SELECT_AC_PATH from the fifteenth input/output terminal of the MCU 32 to the select terminals of the third switching circuit 38 and the pair of fourth switching circuits 40A, 40B is low so that the output voltage of the operational amplifier 54 is provided to the positive terminal of the first energy storage device 14 to charge it. The negative terminal of the first energy storage device 14 is electrically connected to the shunt resistor R5 of the current sensing circuit 46. While the first energy storage device 14 is being charged, voltage and current measurements are detected by the voltage and current sensing circuits 44, 46 and provided to the MCU 32—i.e., to the sixteenth and eighteenth input/output terminals of the MCU 32.

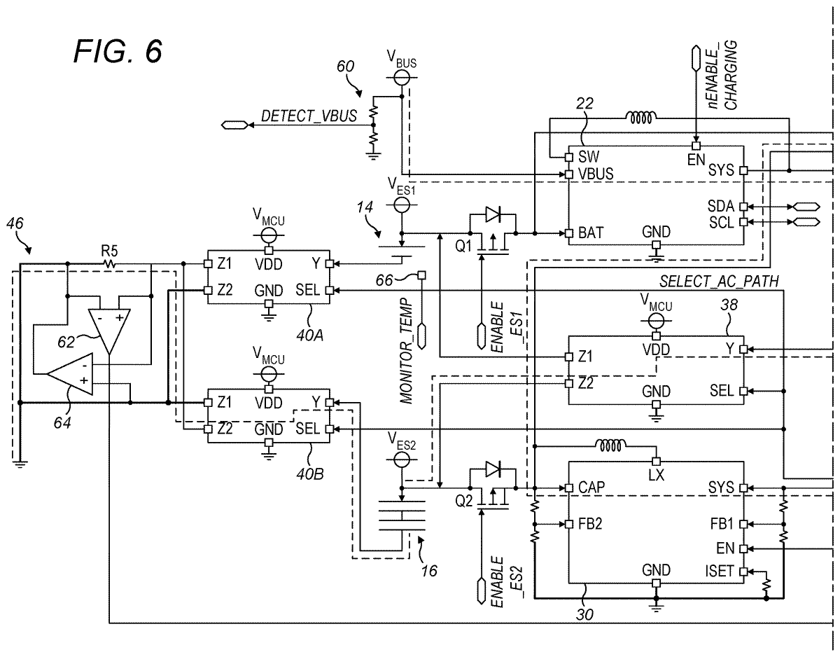

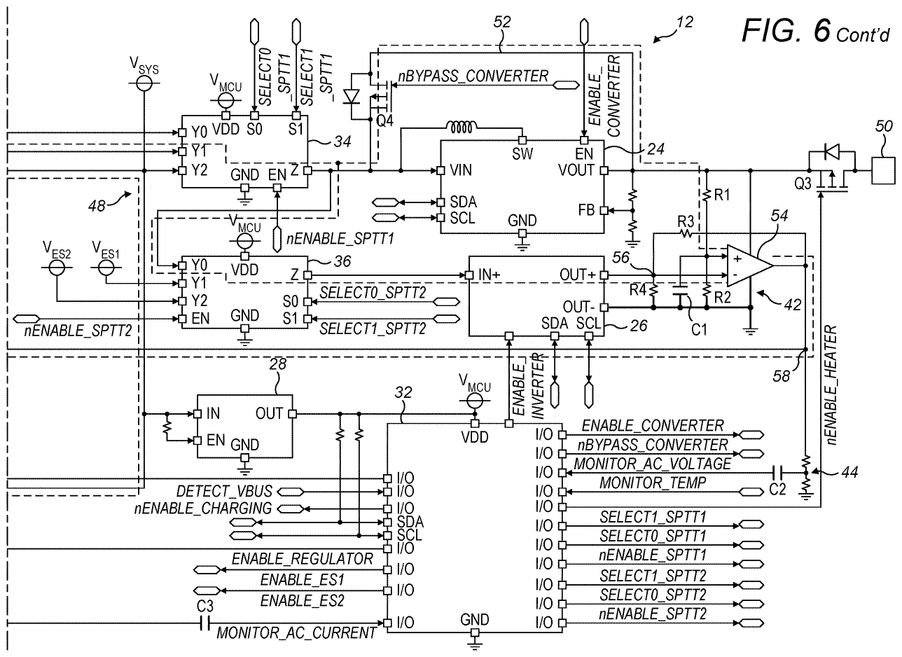

FIG. 6 shows a fourth method of monitoring a condition of the second energy storage device 16 when it is being charged by an external power source (e.g., a USB charger) that is electrically connected to the input terminal of the charging circuit 22. The external power source may be detected by the additional voltage sensing circuit 60, i.e., using the signal DETECT_VBUS that is provided to the MCU 32. The signal DETECT_VBUS turns high once the external power source is detected.

The second semiconductor switch Q2 is switched off by the MCU 32 by sending the enable signal ENABLE_ES2 with a high level from the twelfth input/output terminal.

The charging circuit 22 is disabled. More particularly, the MCU 32 sends a disable signal (i.e., nENABLE_CHARGING with a high level) from the first input/output terminal to the enable terminal of the charging circuit 22.

The DC/DC converter 24 is disabled. More particularly, the MCU 32 sends a disable signal (i.e., ENABLE_CONVERTER with a low level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is enabled. More particularly, the MCU 32 sends an enable signal (i.e., ENABLE_REGULATOR with a high level) from the sixth input/output terminal to the enable terminal of the reversible buck/boost regulator 30.

The first switching circuit 34 is enabled. More particularly, the MCU 32 sends an enable signal (i.e., nENABLE_SPTT1 with a low level) from the fourth input/output terminal to the enable terminal of the first switching circuit 34. The MCU 32 also sends the select signals SELECTS0_SPTT1 and SELECTS1_SPTT2 from the second and third input/output terminals to the select terminal S0, S1 of the first switching circuit 34. The select signal SELECTS0_SPTT1 is high and the select signal SELECTS1_SPTT1 is low and so the second input terminal Y1 is connected to the output terminal Z.

The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signals SELECTS0_SPTT2 and SELECTS1_SPTT2 are low and so the first input terminal Y0 is connected to the output terminal Z.

The third semiconductor switch Q3 is switched off to electrically disconnect the induction heater 50 from the DC/DC converter 24 and the output of the bypass circuit 52. More particularly, the MCU 32 sends the disable signal (i.e., nENABLE_HEATER with a high level) from the thirteenth input/output terminal.

The fourth semiconductor switch Q4 is switched on to bypass the disabled DC/DC converter 24—i.e., so that the voltage input and output terminals are electrically connected through the bypass circuit 52. More particularly, the MCU 32 sends a enable signal (i.e., nBYPASS_CONVERTER with a low level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is high so that the input terminals Y are connected to the respective second output terminal Z2.

A DC charging current from the external power source (not shown) is supplied to the input terminal of the charging circuit 22. The DC current is supplied from the system terminal of the charging circuit 22 to the system terminal of the reversible buck/boost regulator 30 through the system bus 48. The DC current is supplied from the capacitor terminal of the reversible buck/boost regulator 30 to the second input terminal Y1 of the first switching circuit 34, which is connected to the output terminal Z. From the output terminal Z of the first switching circuit 34, the DC current is supplied to the non-inverting input terminal of the operational amplifier 54 of the superimposing circuit 42 through the bypass circuit 52.

At the same time, the DC current is supplied from the output terminal Z of the first switching circuit 34 to the first input terminal Y0 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components.

In this embodiment, both the inverter 26 and the non-inverting input terminal of the operational amplifier 54 receive DC current from the external power source.

The select signal SELECT_AC_PATH from the fifteenth input/output terminal of the MCU 32 to the select terminals of the third switching circuit 38 and the pair of fourth switching circuits 40A, 40B is high so that the output voltage of the operational amplifier 54 is provided to the positive terminal of the second energy storage device 16 to charge it. The negative terminal of the second energy storage device 16 is electrically connected to the shunt resistor R5 of the current sensing circuit 46. While the second energy storage device 16 is being charged, voltage and current measurements are detected by the voltage and current sensing circuits 44, 46 and provided to the MCU 32—i.e., to the sixteenth and eighteenth input/output terminals of the MCU 32.

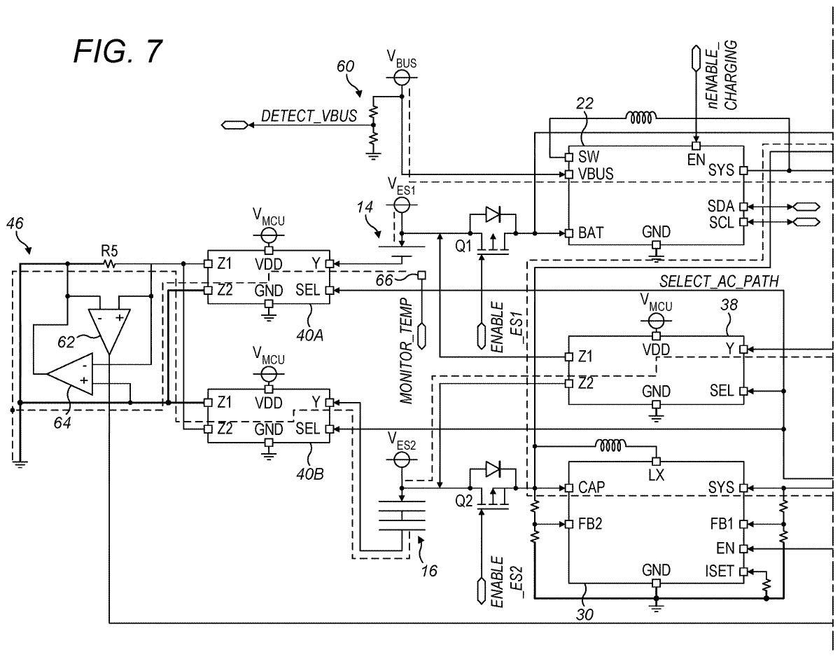

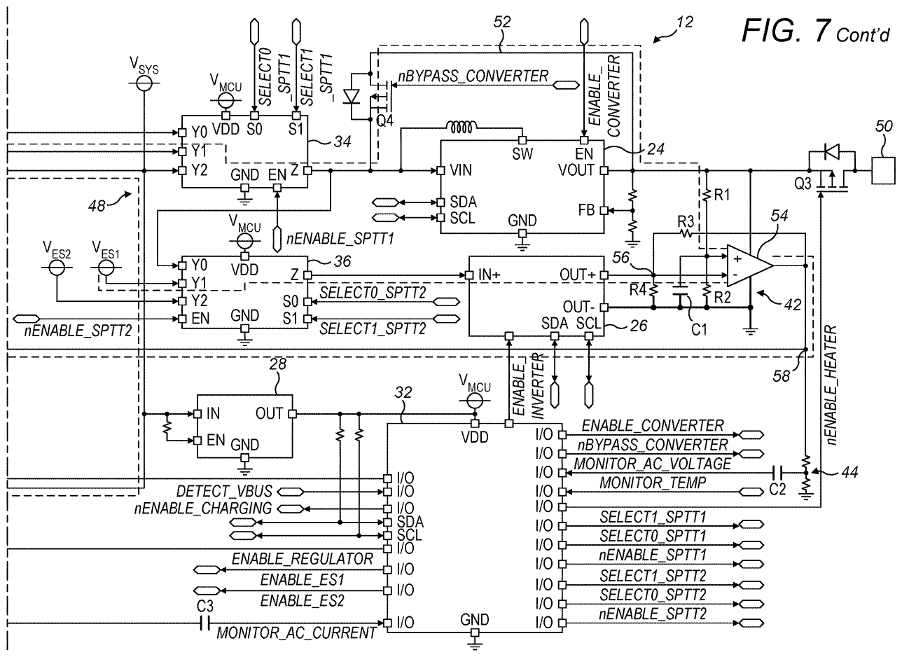

FIG. 7 shows a fifth method of monitoring a condition of the second energy storage device 16 when it is being charged by an external power source (e.g., a USB charger) that is electrically connected to the input terminal of the charging circuit 22. The external power source may be detected by the additional voltage sensing circuit 60, i.e., using the signal DETECT_VBUS that is provided to the MCU 32. The signal DETECT_VBUS turns high once the external power source is connected.

The second semiconductor switch Q2 is switched off by the MCU 32 by sending the enable signal ENABLE_ES2 with a high level from the twelfth input/output terminal.

The charging circuit 22 is disabled. More particularly, the MCU 32 sends a disable signal (i.e., nENABLE_CHARGING with a high level) from the first input/output terminal to the enable terminal of the charging circuit 22.

The DC/DC converter 24 is disabled. More particularly, the MCU 32 sends a disable signal (i.e., ENABLE_CONVERTER with a low level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is enabled. More particularly, the MCU 32 sends an enable signal (i.e., ENABLE_REGULATOR with a high level) from the sixth input/output terminal to the enable terminal of the reversible buck/boost regulator 30.

The first switching circuit 34 is enabled. More particularly, the MCU 32 sends an enable signal (i.e., nENABLE_SPTT1 with a low level) from the fourth input/output terminal to the enable terminal of the first switching circuit 34. The MCU 32 also sends the select signals SELECTS0_SPTT1 and SELECTS1_SPTT1 from the second and third input/output terminals to the select terminal S0, S1 of the first switching circuit 34. The select signal SELECTS0_SPTT1 is high and the select signal SELECTS1_SPTT1 is low and so the second input terminal Y1 is connected to the output terminal Z.

The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signal SELECTS0_SPTT2 is high and the select signal SELECTS1_SPTT2 is low and so the second input terminal Y1 is connected to the output terminal Z.

The third semiconductor switch Q3 is switched off to electrically disconnect the induction heater 50 from the DC/DC converter 24 and the output of the bypass circuit 52. More particularly, the MCU 32 sends a disable signal (i.e., nENABLE_HEATER with a high level) from the thirteenth input/output terminal.

The fourth semiconductor switch Q4 is switched on to bypass the disabled DC/DC converter 24—i.e., so that the voltage input and output terminals are electrically connected through the bypass circuit 52. More particularly, the MCU 32 sends an enable signal (i.e., nBYPASS_CONVERTER with a low level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is high so that the input terminals Y are connected to the respective second output terminal Z2.

A DC charging current from the external power source (not shown) is supplied to the input terminal of the charging circuit 22. The DC current is supplied from the system terminal of the charging circuit 22 to the system terminal of the reversible buck/boost regulator 30 through the system bus 48. The DC current is supplied from the capacitor terminal of the reversible buck/boost regulator 30 to the second input terminal Y1 of the first switching circuit 34, which is connected to the output terminal Z. From the output terminal Z of the first switching circuit 34, the DC current is supplied to the non-inverting input terminal of the operational amplifier 54 of the superimposing circuit 42 through the bypass circuit 52.

DC current is supplied from the positive terminal of the first energy storage device 14 to the second input terminal Y1 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components. In this embodiment, the inverter 26 receives DC current from the first energy storage device 14 and the non-inverting input terminal of the operational amplifier 54 receives DC current from the external power source.

The select signal SELECT_AC_PATH from the fifteenth input/output terminal of the MCU 32 to the select terminals of the third switching circuit 38 and the pair of fourth switching circuits 40A, 40B is high so that the output voltage of the operational amplifier 54 is provided to the positive terminal of the second energy storage device 16 to charge it. The negative terminal of the second energy storage device 16 is electrically connected to the shunt resistor R5 of the current sensing circuit 46. While the second energy storage device 16 is being charged, voltage and current measurements are detected by the voltage and current sensing circuits 44, 46 and provided to the MCU 32—i.e., to the sixteenth and eighteenth input/output terminals of the MCU 32.

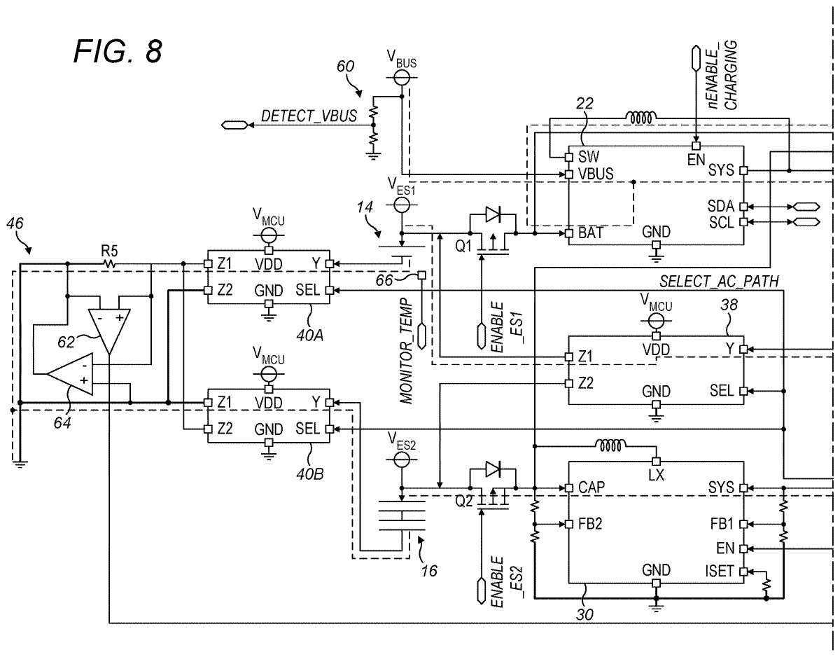

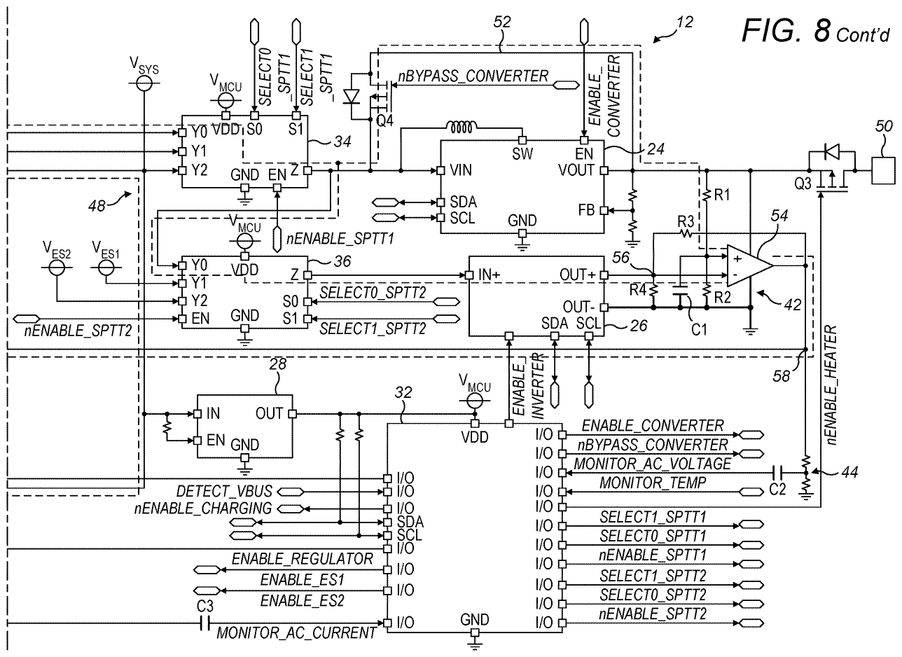

FIG. 8 shows a sixth method of monitoring a condition of the first energy storage device 14 when it is being charged by an external power source (e.g., a USB charger) that is electrically connected to the input terminal of the charging circuit 22. The external power source may be detected by the additional voltage sensing circuit 60, i.e., using the signal DETECT_VBUS that is provided to the MCU 32. The signal DETECT_VBUS turns high once the external power source is connected. The second energy storage device 16 is also being charged by the external power source at the same time.

The first semiconductor switch Q1 is switched off by the MCU 32 by sending the enable signal ENABLE_ES1 with a high level from the eleventh input/output terminal.

The second semiconductor switch Q2 is switched on by the MCU 32 by sending the disable signal ENABLE_ES2 with a low level from the twelfth input/output terminal. The charging circuit 22 is enabled. More particularly, the MCU 32 sends a enable signal (i.e., nENABLE_CHARGING with a low level) from the first input/output terminal to the enable terminal of the charging circuit 22.

The DC/DC converter 24 is disabled. More particularly, the MCU 32 sends a disable signal (i.e., ENABLE_CONVERTER with a low level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is enabled. More particularly, the MCU 32 sends an enable signal (i.e., ENABLE_REGULATOR with a high level) from the sixth input/output terminal to the enable terminal of the reversible buck/boost regulator 30.

The first switching circuit 34 is enabled. More particularly, the MCU 32 sends an enable signal (i.e., nENABLE_SPTT1 with a low level) from the fourth input/output terminal to the enable terminal of the first switching circuit 34. The MCU 32 also sends the select signals SELECTS0_SPTT1 and SELECTS1_SPTT1 from the second and third input/output terminals to the select terminals S0, S1 of the first switching circuit 34.

The select signals SELECTS0_SPTT1 and SELECTS1_SPTT1 are low and so the first input terminal Y0 is connected to the output terminal Z.

The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signals SELECTS0_SPTT2 and SELECTS1_SPTT2 are low and so the first input terminal Y0 is connected to the output terminal Z.

The third semiconductor switch Q3 is switched off to electrically disconnect the induction heater 50 from the DC/DC converter 24 and the output of the bypass circuit 52. More particularly, the MCU 32 sends a disable signal (i.e., nENABLE_HEATER with a high level) from the thirteenth input/output terminal.

The fourth semiconductor switch Q4 is switched on to bypass the disabled DC/DC converter 24—i.e., so that the voltage input and output terminals are electrically connected through the bypass circuit 52. More particularly, the MCU 32 sends an enable signal (i.e., nBYPASS_CONVERTER with a low level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is low so that the input terminals Y are connected to the respective first output terminal Z1.

A DC charging current from the external power source (not shown) is supplied to the input terminal of the charging circuit 22. The DC current is supplied from the system terminal of the charging circuit 22 to the system terminal of the reversible buck/boost regulator 30 through the system bus 48. The DC current is supplied from the capacitor terminal of the reversible buck/boost regulator 30 to the positive terminal of the second energy storage device 16 through the second semiconductor switch Q2, which is switched on. The second energy storage device 16 is therefore charged by the external power source.

The DC current is also supplied from the battery terminal of the charging device 22 to the first input terminal Y0 of the first switching device 34, which is connected to the output terminal Z. From the output terminal Z of the first switching circuit 34, the DC current is supplied to the non-inverting input terminal of the operational amplifier 54 of the superimposing circuit 42 through the bypass circuit 52.

At the same time, the DC current is supplied from the output terminal Z of the first switching circuit 34 to the first input terminal Y0 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components.

In this embodiment, both the inverter 26 and the non-inverting input terminal of the operational amplifier 54 receive DC current from the external power source.

The select signal SELECT_AC_PATH from the fifteenth input/output terminal of the MCU 32 to the select terminals of the third switching circuit 38 and the pair of fourth switching circuits 40A, 40B is low so that the output voltage of the operational amplifier 54 is provided to the positive terminal of the first energy storage device 14 to charge it. The negative terminal of the first energy storage device 14 is electrically connected to the shunt resistor R5 of the current sensing circuit 46. The negative terminal of the second energy storage device 16 is electrically connected directly to ground. While the first energy storage device 14 is being charged, voltage and current measurements are detected by the voltage and current sensing circuits 44, 46 and provided to the MCU 32—i.e., to the sixteenth and eighteenth input/output terminals of the MCU 32.

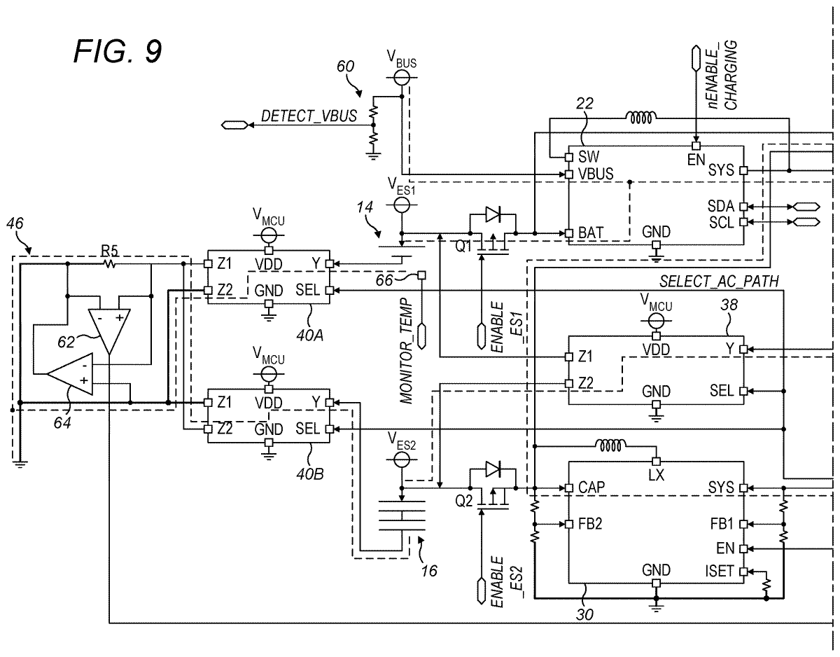

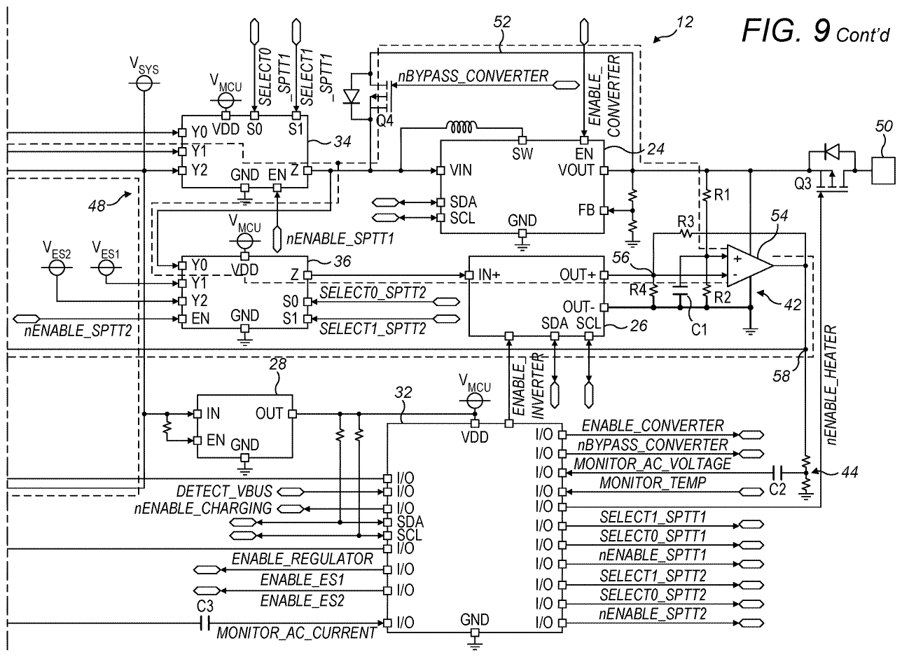

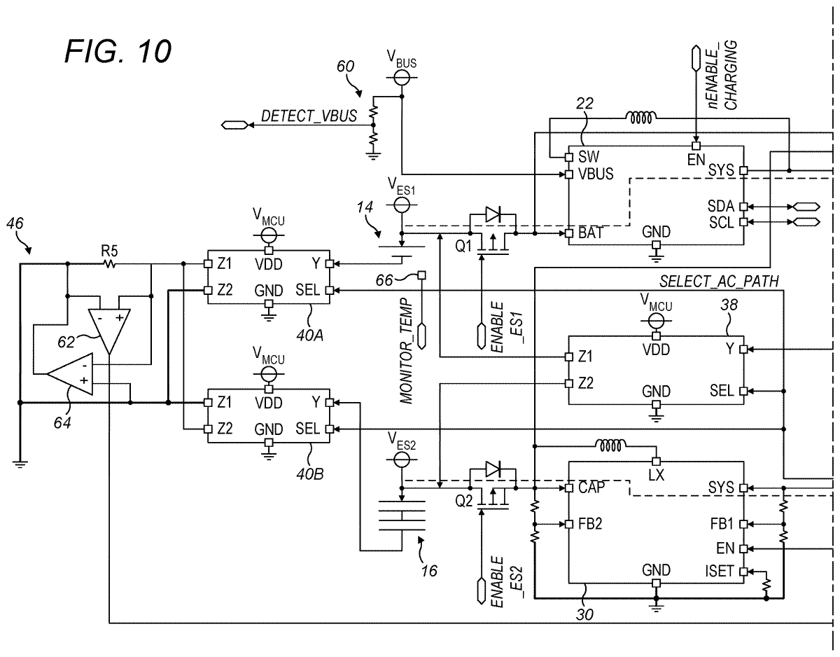

FIG. 9 shows a seventh method of monitoring a condition of the second energy storage device 16 when it is being charged by an external power source (e.g., a USB charger) that is electrically connected to the input terminal of the charging circuit 22. The external power source may be detected by the additional voltage sensing circuit 60, i.e., using the signal DETECT_VBUS that is provided to the MCU 32. The signal DETECT_VBUS turns high once the external power source is connected. The first energy storage device 14 is also being charged by the external power source at the same time.

The first semiconductor switch Q1 is switched on by the MCU 32 by sending the disable signal ENABLE_ES1 with a low level from the eleventh input/output terminal.

The second semiconductor switch Q2 is switched off by the MCU 32 by sending the enable signal ENABLE_ES2 with a high level from the twelfth input/output terminal.

The charging circuit 22 is enabled. More particularly, the MCU 32 sends a enable signal (i.e., nENABLE_CHARGING with a low level) from the first input/output terminal to the enable terminal of the charging circuit 22.

The DC/DC converter 24 is disabled. More particularly, the MCU 32 sends a disable signal (i.e., ENABLE_CONVERTER with a low level) from the fifth input/output terminal to the enable terminal of the DC/DC converter 24.

The inverter 26 is enabled. More particularly, the MCU 32 sends an enable signal (i.e., ENABLE_INVERTER with a high level) from the tenth input/output terminal to the enable terminal of the inverter 26.

The reversible buck/boost regulator 30 is enabled. More particularly, the MCU 32 sends an enable signal (i.e., ENABLE_REGULATOR with a high level) from the sixth input/output terminal to the enable terminal of the reversible buck/boost regulator 30.

The first switching circuit 34 is enabled. More particularly, the MCU 32 sends an enable signal (i.e., nENABLE_SPTT1 with a low level) from the fourth input/output terminal 25 to the enable terminal of the first switching circuit 34. The MCU 32 also sends the select signals SELECTS0_SPTT1 and SELECTS1_SPTT1 from the second and third input/output terminals to the select terminals S0, S1 of the first switching circuit 34.

The select signal SELECTS0_SPTT1 is high and the select signal SELECTS1_SPTT1 is low and so the second input terminal Y1 is connected to the output terminal Z.

The second switching circuit 36 is enabled. More particularly, the MCU 32 sends an enable signal (i.e., nENABLE_SPTT2 with a low level) from the ninth input/output terminal to the enable terminal of the second switching circuit 36. The MCU 32 also sends the select signals SELECTS0_SPTT2 and SELECTS1_SPTT2 from the seventh and eighth input/output terminals to the select terminals S0, S1 of the second switching circuit 36. The select signals SELECTS0_SPTT2 and SELECTS1_SPTT2 are low and so the first input terminal Y0 is connected to the output terminal Z.

The third semiconductor switch Q3 is switched off to electrically disconnect the induction heater 50 from the DC/DC converter 24 and the output of the bypass circuit 52. More particularly, the MCU 32 sends a disable signal (i.e., nENABLE_HEATER with a high level) from the thirteenth input/output terminal.

The fourth semiconductor switch Q4 is switched on to bypass the disabled DC/DC converter 24—i.e., so that the voltage input and output terminals are electrically connected through the bypass circuit 52. More particularly, the MCU 32 sends an enable signal (i.e., nBYPASS_CONVERTER with a low level) from the fourteenth input/output terminal.

The MCU 32 sends the select signal SELECT_AC_PATH from the fifteenth input/output terminal to the select terminals of the third switching circuit 38 and the fourth switching circuits 40A, 40B. The select signal SELECT_AC_PATH is high so that the input terminals Y are connected to the respective second output terminal Z2.

A DC charging current from the external power source (not shown) is supplied to the input terminal of the charging circuit 22. The DC current is supplied from the battery terminal of the charging device 22 to the positive terminal of the first energy storage device 14 through the first semiconductor switch Q1, which is switched on. The first energy storage device 14 is therefore charged by the external power source.

The DC current is also supplied from the system terminal of the charging circuit 22 to the system terminal of the reversible buck/boost regulator 30 through the system bus 48. The DC current is supplied from the capacitor terminal of the reversible buck/boost regulator 30 to the second input terminal Y1 of the first switching circuit 34, which is connected to the output terminal Z. From the output terminal Z of the first switching circuit 34, the DC current is supplied to the non-inverting input terminal of the operational amplifier 54 of the superimposing circuit 42 through the bypass circuit 52.

At the same time, the DC current is supplied from the output terminal Z of the first switching circuit 34 to the first input terminal Y0 of the second switching circuit 36, which is connected to the output terminal Z. From the output terminal Z of the second switching circuit 36, the DC current is supplied to the inverter 26. The inverter 26 provides an AC signal to the superimposing circuit 42—i.e., the inverting input terminal of the operational amplifier 54. The AC signal from the inverter 26 is superimposed on the DC current supplied to the non-inverting input terminal of the operational amplifier 54 through the bypass circuit 52 so that the output of the superimposing circuit—i.e., the output voltage of the operational amplifier 54—has both AC and DC components.

In this embodiment, both the inverter 26 and the non-inverting input terminal of the operational amplifier 54 receive DC current from the external power source.

The select signal SELECT_AC_PATH from the fifteenth input/output terminal of the MCU 32 to the select terminals of the third switching circuit 38 and the pair of fourth switching circuits 40A, 40B is high so that the output voltage of the operational amplifier 54 is provided to the positive terminal of the second energy storage device 16 to charge it. The negative terminal of the second energy storage device 16 is electrically connected to the shunt resistor R5 of the current sensing circuit 46. The negative terminal of the first energy storage device 14 is electrically connected directly to ground. While the second energy storage device 16 is being charged, voltage and current measurements are detected by the voltage and current sensing circuits 44, 46 and provided to the MCU 32—i.e., to the sixteenth and eighteenth input/output terminals of the MCU 32.

To obtain the condition of the first or second energy storage device 14, 16 when it is being charged, the MCU 32 uses the voltage and current measurements obtained from the voltage and current sensing circuits 44, 46 to determine a series of internal impedance values. For the purpose of the following discussion, it will be assumed that it is the first energy storage device 14 that is being charged, but it will be understood that the same process may be used to monitor the second energy storage device 16, e.g., when it is charged by the external power source as shown in FIGS. 6 to 9.

First, the MCU 32 will use the instantaneous voltage and current measurements to determine the RMS values of the voltage and current Vᵣₘₛ and Iᵣₘₛ as follows:

$${V}_{rms}^{2} = \frac{1}{T} {\int }_{0}^{T} {v}^{2} ( t ) dt$$

$${I}_{rms}^{2} = \frac{1}{T} {\int }_{0}^{T} {i}^{2} ( t ) dt$$

where T is the period over which the averaging of the instantaneous voltages and currents is performed.

Once the RMS values are known for the given frequency f of the AC signal (f=)ω/2π where ω is the angular frequency), the magnitude of the internal impedance Z of the first energy storage device 14 may be estimated or determined by the MCU 32 as follows:

$$\vert Z ( ω ) \vert = \sqrt{\frac{{V}_{rms}^{2} ( ω )}{{I}_{rms}^{2} ( ω )}}$$

The average of the first few values of the internal impedance (e.g., the first 3-5 values) is taken as an initial (or reference) value. The initial value may be compared against one or more threshold to estimate or determine a condition of the first energy storage device 14. For example, if the initial value is above a first threshold it may indicate that the first energy storage device 14 needs to be replaced and if it is above a second threshold, that is higher than the first threshold, it may indicate that the first energy storage device 14 is not suitable for operation and that charging should be stopped. An appropriate notification may be provided to the user.

Subsequent internal impedance values may be determined during the charging of the first energy storage device 14. These subsequent values may also be compared against one or more thresholds to estimate or determine a condition of the first energy storage device 14 during charging. For example, if a subsequent value is below a threshold, it may indicate that the internal temperature of the first energy storage device 14 is too high and that charging should be stopped. Charging may be stopped if the internal impedance decreases by more than about 20-40% of the initial value, for example.

The MCU 32 also receives temperature measurements from the temperature sensor 66 that is positioned on an outer surface of the housing of the first energy storage device 14. Temperature measurements provided by the temperature sensor 66 during charging are compared with the internal impedance values determined by the MCU 32 while the first energy storage device 14 is being charged. The comparison may be used to determine if the temperature measurements are plausible, i.e., if they are valid or not.

For example, if the internal impedance values decrease by a certain amount (e.g., by about x ohms or about x %) without a respective increase in surface temperature (e.g., by about y degrees or about y %) being measured by the temperature sensor 66, the validity of the temperature measurements may be set as “not valid” and the user may be notified. Other comparisons between the impedance values and the temperature measurements may also be used.

To charge the first energy storage device 14 from an external power source that is electrically connected to the input terminal of the charging circuit 22, without an AC signal being applied, it is necessary only to enable the charging circuit 22 and switch on the first semiconductor switch Q1. DC charging current may therefore be supplied to the input terminal of the charging circuit 22, and from the battery terminal of the charging circuit 22 to the positive terminal of the first energy storage device 14. The negative terminal of the first energy storage device 14 may be electrically connected directly to the ground connection of the current sensing circuit 46 by setting the select signal SELECT_AC_PATH to be high. To charge the second energy storage device 16 from an external power source that is electrically connected to the input terminal of the charging circuit 22, without an AC signal being applied, it is necessary only to enable the charging circuit 22 and the reversible buck/boost regulator 30 and switch on the second semiconductor switch Q2. DC charging current may therefore be supplied to the input terminal of the charging circuit 22, from the system terminal of the charging circuit 22 to the system terminal of the reversible buck/boost regulator 30 operating in a buck mode by means of the system bus 48, and from the capacitor terminal of the reversible buck/boost regulator 30 to the positive terminal of the second energy storage device 16. The negative terminal of the second energy storage device 16 may be electrically connected directly to the ground connection of the current sensing circuit 46 by setting the select signal SELECT_AC_PATH to be low.

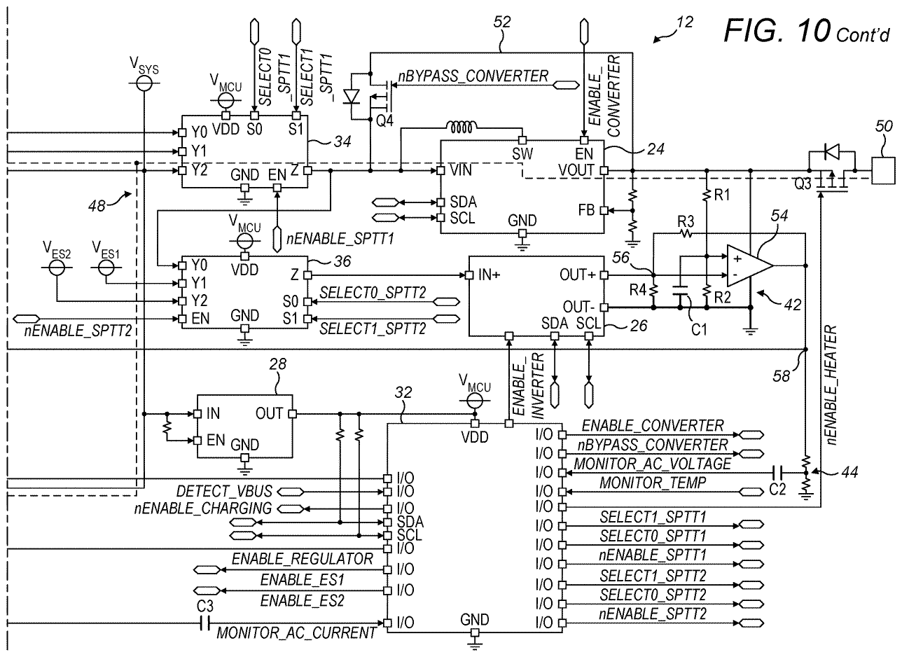

FIG. 10 shows how the first and/or second energy storage devices 14, 16 may be discharged to supply power to the induction heater 50. The third semiconductor switch Q3 is switched on to electrically connect the induction heater 50 to the voltage output terminal of the DC/DC converter 24, which is enabled. More particularly, the MCU 32 sends an enable signal (i.e., ENABLE_CONVERTER with a high level) from the fifth input/output terminal to the enable terminal of the DC/DC converter 24 and an enable signal (i.e., nENABLE_HEATER with a low level) from the thirteenth input/output terminal to the third semiconductor switch Q3. The fourth semiconductor switch Q4 is switched off More particularly, the MCU 32 sends a disable signal (i.e., nBYPASS_CONVERTER with a high level) from the fourteenth input/output terminal.

The first switching circuit 34 is enabled. More particularly, the MCU 32 sends an enable signal (i.e., nENABLE_SPTT1 with a low level) from the fourth input/output terminal to the enable terminal of the first switching circuit 34. The second switching circuit 36 is disabled. More particularly, the MCU 32 sends a disable signal (i.e., nENABLE_SPTT2 with a high level) from the ninth input/output terminal to the enable terminal of the second switching circuit 36.

If the first energy storage device 14 is to be discharged, the charging circuit 22 is enabled to supply DC current to the third input terminal Y2 of the first switching circuit 34. In particular, DC current flows from the first energy storage device 14 to the battery terminal of the charging circuit 22 through the body diode of the first semiconductor switch Q1. The select signal SELECTS0_SPTT1 is set to be low and the select signal SELECTS1_SPTT1 is set to be high so that the third input terminal Y2 of the first switching circuit 34 is connected to the output terminal Z. DC current is therefore supplied from the output terminal Z to the voltage input terminal of the DC/DC converter 24. The DC/DC converter 24 supplies a boosted DC current to the induction heater 50.

If the second energy storage device 16 is to be discharged, the reversible buck/boost regulator 30 is enabled to supply DC current to the third input terminal Y2 of the first switching circuit 34. In particular, DC current flows from the second energy storage device 16 to the capacitor terminal of the reversible buck/boost regulator 30 through the body diode of the second semiconductor switch Q2. If both the first and second energy storage devices 14, 16 are being discharged simultaneously, the third input terminal Y2 of the first switching device 34 with receive DC current from both the charging circuit 22 and the reversible buck/boost regulator 30. The select signal SELECTS0_SPTT1 is set to be low and the select signal SELECTS1_SPTT1 is set to be high so that the third input terminal Y2 is connected to the output terminal Z. DC current is therefore supplied from the output terminal Z to the voltage input terminal of the DC/DC converter 24. The DC/DC converter 24 supplies a boosted DC current to the induction heater 50.

Although exemplary embodiments have been described in the preceding paragraphs, it should be understood that various modifications may be made to those embodiments without departing from the scope of the appended claims. Thus, the breadth and scope of the claims should not be limited to the above-described exemplary embodiments.

Any combination of the above-described features in all possible variations thereof is encompassed by the present disclosure unless otherwise indicated herein or otherwise clearly contradicted by context.

Unless the context clearly requires otherwise, throughout the description and the claims, the words “comprise”, “comprising”, and the like, are to be construed in an inclusive as opposed to an exclusive or exhaustive sense; that is to say, in the sense of “including, but not limited to”.

1. A method of monitoring an aerosol generating system comprising a first energy storage device configured to supply power to generate an aerosol, the method comprising:
charging the first energy storage device with a direct current DC charging current supplied by an external power source or a second energy storage device of the aerosol generating system;
while the first energy storage device is being charged, applying an alternating current AC signal to the first energy storage device;
using voltage and current measurements obtained in response to the applied AC signal to estimate or determine the impedance of the first energy storage device; and
using the impedance of the first energy storage device to estimate or determine a condition of the first energy storage device.

2. The method according to claim 1, wherein the AC signal applied to the first energy storage device is superimposed on the DC charging current.

3. The method according to claim 1, wherein the aerosol generating system further comprises a second energy storage device, and wherein the method comprises:
charging the first and second energy storage devices with a DC charging current supplied by an external power source; and
while the first and second energy storage devices are being charged, superimposing the AC signal on the DC charging current supplied to the first energy storage device.

4. A method of monitoring an aerosol generating system comprising an energy storage device configured to supply power to generate an aerosol, and a temperature sensor configured to measure a temperature of the energy storage device, the method comprising:
charging the energy storage device with a DC charging current; while the energy storage device is being charged, applying an AC signal to the energy storage device;
using voltage and current measurements obtained in response to the applied AC signal to estimate or determine the impedance of the energy storage device; and
using the impedance of the energy storage device to determine if the temperature measurements provided by the temperature sensor are valid.

5. An aerosol generating system comprising:
a first energy storage device;
an inverter electrically connected to the first energy storage device and configured to supply an AC signal;
a superimposing circuit electrically connected to the inverter and the first energy storage device, wherein the superimposing circuit is configured to impose the AC signal supplied by the inverter on a DC charging current supplied by an external power source or a second energy storage device of the aerosol generating system; and
a controller configured to:
supply a DC charging current and a superimposed AC signal to the first energy storage device to charge the first energy storage device,
use voltage and current measurements obtained in response to the AC signal to estimate or determine the impedance of the first energy storage device, and
use the impedance to estimate or determine a condition of the first energy storage device.

6. The aerosol generating system according to claim 5, further comprising:
a charging circuit electrically connectable to the external power source; and
a switch electrically connected between the charging circuit and the first energy storage device;
wherein an input of the superimposing circuit is electrically connected between the charging circuit and the switch;
wherein an output of the superimposing circuit is electrically connected between the switch and the first energy storage device; and
wherein the controller is further configured to open the switch when the AC signal is supplied to the first energy storage device.

7. The aerosol generating system according to claim 6, wherein the controller is further configured to close the switch when the AC signal is not supplied to the first energy storage device and a DC charging current supplied by the external power source is supplied to the first energy storage device.

8. The aerosol generating system according to claim 5, further comprising the second energy storage device, wherein an input of the superimposing circuit is electrically connected to the second energy storage device.

9. The aerosol generating system according to claim 5, further comprising the second energy storage device, wherein an output of the superimposing circuit is electrically connected to the second energy storage device.

10. The aerosol generating system according to claim 8, further comprising a first switching circuit electrically connected between the superimposing circuit and the second energy storage device, wherein the first switching circuit is electrically connectable to the external power source, and wherein the first switching circuit is configured to selectively connect an input of the superimposing circuit to one of the second energy storage device and the external power source.

11. The aerosol generating system according to claim 10, wherein the first switching circuit is electrically connected to the first energy storage device, and wherein the first switching circuit is configured to selectively connect the input of the superimposing circuit to one of the first energy storage device, the second energy storage device, and the external power source.

12. The aerosol generating system according to claim 10, further comprising a second switching circuit electrically connected between the inverter and the second energy storage device, wherein the second switching circuit is electrically connectable to the external power source, and wherein the second switching circuit is configured to selectively connect an input of the inverter to one of the second energy storage device and the external power source.

13. The aerosol generating system according to claim 12, wherein the second switching circuit is electrically connected to the first energy storage device, and wherein the second switching circuit is configured to selectively connect the input of the inverter to one of the first energy storage device, the second energy storage device, and the external power source.

14. The aerosol generating system according to claim 5, further comprising a voltage sensing circuit configured to measure the voltage across the first energy storage device when the AC signal is supplied to the first energy storage device, wherein the voltage sensing circuit is electrically connected between an output of the superimposing circuit and the first energy storage device.

15. The aerosol generating system according to claim 5, further comprising a current sensing circuit configured to measure the current through the first energy storage device when the AC signal is supplied to the first energy storage device, wherein the current sensing circuit includes a shunt resistor and a current sensing amplifier electrically connected with the shunt resistor, and wherein the aerosol generating system further comprises a switching circuit electrically connected to the first energy storage device and configured to selectively connect the first energy storage device directly to ground or to ground via the shunt resistor of the current sensing device.
